(19) United States
(12) Patent Application Publication
(10) Pub. No.: US 2024/0428734 A1
(43) Pub. Date: Dec. 26, 2024

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Binyan WANG, Beijing (CN); Cong LIU, Beijing (CN); Yuanyou QIU, Beijing (CN); Zhiliang JIANG, Beijing (CN)

(21) Appl. No.: 18/703,375

(22) PCT Filed: May 17, 2023
(86) PCT No.: PCT/CN2023/094828

§ 371 Date: Apr. 22, 2024

(30) Foreign Application Priority Data
Jun. 14, 2022 (CN) 202210672807.4

(51) Int. Cl. G09G 3/3233

(52) U.S. Cl. CPC G09G 3/3233; G09G 2300/0426; G09G 2330/023

(57) ABSTRACT

A display substrate including a display area is provided. The display area includes: a base, and a plurality of pixel circuits, a plurality of data lines and a plurality of data compensation units, wherein the pixel circuits, the data lines and the data compensation units are arranged on the base; and at least one of the plurality of data lines is electrically connected to the plurality of pixel circuits which are arranged in a first direction, and is further electrically connected to the at least one data compensation unit.

### CROSS-REFERENCE TO RELATED APPLICATIONS

The present application is a U.S. National Phase Entry of International Application No. PCT/CN2023/094828 having an international filing date of May 17, 2023, which claims priority of Chinese Patent Application No. 202210672807.4, filed on Jun. 14, 2022, to the China National Intellectual Property Administration, entitled “DISPLAY SUBSTRATE AND DISPLAY APPARATUS”. The above-identified applications are hereby incorporated by reference.

### TECHNICAL FIELD

The present disclosure relates to, but is not limited to, the field of display technologies, in particular to a display substrate and a display apparatus.

### BACKGROUND

An Organic Light Emitting Diode (OLED) and a Quantum dot Light Emitting Diode (QLED) are active light emitting display devices and have advantages of self-luminescence, a wide viewing angle, a high contrast ratio, low power consumption, an extremely high response speed, lightness and thinness, bendability, and a low cost, etc.

### SUMMARY

The following is a summary of subject matters described herein in detail. This summary is not intended to limit the protection scope of claims.

Embodiments of the present disclosure provide a display substrate and a display apparatus.

In one aspect, the present embodiment provides a display substrate including: a display region. The display region includes a base substrate and a plurality of pixel circuits, a plurality of data lines and a plurality of data compensation units arranged on the base substrate. At least one of the plurality of data lines is electrically connected to a plurality of pixel circuits arranged in a first direction, and is electrically connected to at least one data compensation unit.

In some exemplary embodiments, the plurality of pixel circuits of the display region are arranged in a plurality of rows and a plurality of columns, the plurality of pixel circuits arranged in the first direction are a column of pixel circuits, and a plurality of pixel circuits arranged in a second direction are a row of pixel circuits. The first direction intersects the second direction. The plurality of data compensation units are arranged between a plurality of rows of pixel circuits in the first direction.

In some exemplary embodiments, at least one row of pixel circuits is provided between at least two adjacent data compensation units arranged in the first direction.

In some exemplary embodiments, the at least one data line is electrically connected to a plurality of data compensation units arranged in the first direction.

In some exemplary embodiments, a plurality of data compensation units arranged in a second direction are one row of data compensation units; the at least one data line is electrically connected with a plurality of data compensation units in at least one row of data compensation units; the second direction intersects the first direction.

In some exemplary embodiments, the display region is a circular region.

In some exemplary embodiments, the display region includes: a first display region and a second display region, the first display region is located at at least one side of the second display region. The plurality of pixel circuits of the display region includes a plurality of first pixel circuits and a plurality of second pixel circuits located in the first display region. The first display region further comprises a plurality of first light emitting elements. The second display region further comprises a plurality of second light emitting elements at least one first pixel circuit of the plurality of first pixel circuits is electrically connected to at least one first light emitting element of the plurality of first light emitting elements, and at least one second pixel circuit of the plurality of second pixel circuits is electrically connected to at least one second light emitting element of the plurality of second light emitting elements.

In some exemplary embodiments, a length of an active layer of a drive transistor of the at least one second pixel circuit along the first direction is smaller than a length of an active layer of a drive transistor of the at least one first pixel circuit along the first direction.

In some exemplary embodiments, the data compensation unit includes: a first compensation electrode plate and a second compensation electrode plate, an orthographic projection of the first compensation electrode plate on the base substrate at least partially overlaps an orthographic projection of the second compensation electrode plate on the base substrate; the first compensation electrode plate is electrically connected with the data line, and the second compensation electrode plate is electrically connected with a first signal line.

In some exemplary embodiments, the first signal line includes a first power supply line.

In some exemplary embodiments, in a direction perpendicular to the display substrate, the display region includes: a base substrate, and a semiconductor layer, a first conductive layer, a second conductive layer, a third conductive layer, and a fourth conductive layer disposed on the base substrate. The semiconductor layer at least includes: active layers of transistors of the plurality of pixel circuits. The first conductive layer at least comprises: gate electrodes of transistors of the plurality of pixel circuits, first capacitor electrode plates of storage capacitors of the plurality of pixel circuits. The second conductive layer at least comprises: second capacitor electrode plates of the storage capacitors of the plurality of pixel circuits. The third conductive layer at least comprises a plurality of connection electrodes. The fourth conductive layer at least comprises: the plurality of data lines. The first compensation electrode plate and the second compensation electrode plate of the data compensation unit are located in different conductive layers among the first conductive layer to the fourth conductive layer.

In some exemplary embodiments, the first compensation electrode plate is located in the first conductive layer and the second compensation electrode plate is located in the second conductive layer; or, the first compensation electrode plate is located in the second conductive layer, and the first compensation electrode plate is located in the first conductive layer.

In some exemplary embodiments, the first compensation electrode plate is located at a side of the second compensation electrode plate close to the base substrate. The data compensation unit further comprises: a third compensation electrode plate electrically connected with the first compensation electrode plate; an orthographic projection of the third compensation electrode plate on the base substrate at least partially overlaps an orthographic projection of the second compensation electrode plate on the base substrate, the third compensation electrode plate is located at a side of the second compensation electrode plate away from the base substrate.

In some exemplary embodiments, the first compensation electrode plate is located at a side of the second compensation electrode plate away from the base substrate. The data compensation unit further comprises: a fourth compensation electrode plate electrically connected with the second compensation electrode plate; an orthographic projection of the fourth compensation electrode plate on the base substrate at least partially overlaps an orthographic projection of the first compensation electrode plate on the base substrate, the fourth compensation electrode plate is located at a side of the first compensation electrode plate away from the base substrate.

In another aspect, a display apparatus is provided in an embodiment of the present disclosure, which includes the aforementioned display substrate.

In some exemplary embodiments, the display apparatus further includes a sensor located on a side of a non-display surface of the display substrate, wherein an orthographic projection of the sensor on the display substrate is at least partially overlapped with a second display region of the display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a display substrate according to at least one embodiment of the present disclosure;

FIG. 2 is a schematic diagram of another display substrate according to at least one embodiment of the present disclosure;

FIG. 3 is a partial schematic diagram of the display substrate shown in FIG. 2;

FIG. 4A is a schematic diagram of a connection between a data line and a data compensation unit according to at least one embodiment of the present disclosure;

FIG. 4B is schematic diagram of another connection between a data line and a data compensation unit according to at least one embodiment of the present disclosure;

FIG. 4C is schematic diagram of another connection between a data line and a data compensation unit according to at least one embodiment of the present disclosure;

FIG. 5 is an equivalent circuit diagram of a pixel circuit according to at least one embodiment of the present disclosure.

FIG. 6 is a partial top view of a first display region according to at least one embodiment of the present disclosure.

FIG. 7A is a partial sectional view along a P-P′ direction in FIG. 6.

FIG. 7B is a partial sectional view along a Q-Q′ direction in FIG. 6.

FIG. 8 is a schematic diagram of a first display region after a semiconductor layer is formed in FIG. 6;

FIG. 9A is a schematic diagram of a first display region after a first conductive layer is formed in FIG. 6.

FIG. 9B is a schematic diagram of a first conductive layer in FIG. 9A.

FIG. 10A is a schematic diagram of a first display region after a second conductive layer is formed in FIG. 6.

FIG. 10B is a schematic diagram of a second conductive layer in FIG. 10A.

FIG. 11 is a schematic diagram of a first display region after a third insulating layer is formed in FIG. 6;

FIG. 12A is a schematic diagram of a first display region after a third conductive layer is formed in FIG. 6.

FIG. 12B is a schematic diagram of a third conductive layer in FIG. 12A.

FIG. 13 is a schematic diagram of a first display region after a fourth insulating layer is formed in FIG. 6;

FIG. 14 is a schematic diagram of a fourth conductive layer in FIG. 6.

FIG. 15A is another partial top view of a first display region according to at least one embodiment of the present disclosure;

FIG. 15B is a schematic diagram of a first display region after a fourth conductive layer is formed in FIG. 15A;

FIG. 16 is another schematic diagram of a partial structure of a first display region according to at least one embodiment of the present disclosure;

FIG. 17 is a partial sectional view in a direction R-R′in FIG. 16;

FIG. 18 is a schematic diagram of a first display region after a first conductive layer is formed in FIG. 16.

FIG. 19 is a schematic diagram of a first display region after a second conductive layer is formed in FIG. 16.

FIG. 20 is a schematic diagram of a first display region after a third insulating layer is formed in FIG. 16;

FIG. 21A is a schematic diagram of a first display region after a third conductive layer is formed in FIG. 16.

FIG. 21B is a schematic diagram of a third conductive layer in FIG. 21A.

FIG. 22 is a schematic diagram of a first display region after a fourth insulating layer is formed in FIG. 16;

FIG. 23 is a schematic diagram of a display apparatus according to at least one embodiment of the present disclosure.

### DETAILED DESCRIPTION

The embodiments of the present disclosure will be described below with reference to the drawings in detail. Embodiments may be implemented in multiple different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating orientation or positional relationships are used to illustrate positional relationships between the composition elements with reference to the drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, other elements with multiple functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification. In addition, the gate may also be referred to as a control electrode.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In this specification, a circle, oval, triangle, rectangle, trapezoid, pentagon or hexagon, etc. is not strictly speaking, but may be an approximate circle, oval, triangle, rectangle, trapezoid, pentagon or hexagon, etc. Some small deformations due to tolerances may exist, for example, guide angles, curved edges and deformations thereof may exist.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. “A extends in the B direction” in the present disclosure means “the main portion of A extends in the B direction”.

Embodiments of the present disclosure provide a display substrate, which includes a display region. The display region includes a base substrate and a plurality of pixel circuits, a plurality of data lines and a plurality of data compensation units provided on the base substrate. At least one of the plurality of data lines is electrically connected to a plurality of pixel circuits arranged in a first direction, and is also electrically connected to at least one data compensation unit.

The display substrate according to the present embodiment can perform load compensation on a data line by electrically connecting the data line with a data compensation unit, thereby ensuring the display consistency of the display region. Moreover, by providing the data compensation unit in the display region, it is possible to avoid occupying a bezel region of the display substrate, thereby facilitating the achievement of a narrow bezel.

In some exemplary embodiments, the plurality of pixel circuits of the display region may be arranged in a plurality of rows and a plurality of columns. A plurality of pixel circuits arranged in the first direction may be a column of pixel circuits, and a plurality of pixel circuits arranged in a second direction may be a row of pixel circuits. The first direction and the second direction may intersect. For example, the first direction may be perpendicular to the second direction. The plurality of data compensation units may be arranged between a plurality of rows of pixel circuits in the first direction. For example, a plurality of data compensation units arranged in the first direction may be a column of data compensation units. At least one row of pixel circuits may be provided between at least two adjacent data compensation units in a column of data compensation units, for example, a row of pixel circuits may be provided or a plurality of rows of pixel circuits may be provided. A quantity of rows of pixel circuits provided between any two adjacent data compensation units in a column of data compensation units may be the same or may be different. However, the embodiment is not limited thereto.

In some exemplary embodiments, at least one data line is electrically connected to a plurality of data compensation units arranged in the first direction. For example, at least one data line may be electrically connected to at least two adjacent data compensation units arranged in the first direction. For example, at least one data line may be electrically connected to a data compensation unit through a compensation connection electrode. However, the embodiment is not limited thereto.

In some exemplary embodiments, a plurality of data compensation units arranged in a second direction may be referred to as one row of data compensation units. At least one data line may be electrically connected to a plurality of data compensation units in at least one row of data compensation units. For example, one data line may be electrically connected to a plurality of data compensation units in a row of data compensation units, or one data line may be electrically connected to a plurality of data compensation units in a plurality of rows of data compensation units. A plurality of data compensation units electrically connected to a same data line in a row of data compensation units may be adjacent and may be electrically connected through compensation connection electrodes.

In some exemplary embodiments, the display region may be a circular region. However, the embodiment is not limited thereto. For example, the display region can be oval, pentagon, hexagon, or other irregular shape.

In some exemplary embodiments, the display region may include a first display region and a second display region. The first display region may be located at at least one side of the second display region. The plurality of pixel circuits of the display region may include a plurality of first pixel circuits and a plurality of second pixel circuits located in the first display region. The first display region may further include a plurality of first light emitting elements, and the second display region may further include a plurality of second light emitting elements. At least one first pixel circuit of the plurality of first pixel circuits is electrically connected to at least one first light emitting element of the plurality of first light emitting elements, and at least one second pixel circuit of the plurality of second pixel circuits is electrically connected to at least one second light emitting element of the plurality of second light emitting elements. At least one first pixel circuit may be configured to drive at least one first light emitting element to emit light, and at least one second pixel circuit may be configured to drive at least one second light emitting element to emit light. The display substrate according to this example can be applied to a display apparatus with an under-screen sensor.

In some exemplary embodiments, a length of an active layer of a drive transistor of a second pixel circuit in the first direction may be smaller than a length of an active layer of a drive transistor of a first pixel circuit in the first direction. In this example, by reducing the length of the active layer of the drive transistor of the second pixel circuit, a threshold voltage of the drive transistor can be positively biased, and a driving current provided by the second pixel circuit can be increased under the condition that a gate-source voltage difference of the drive transistor is unchanged, thereby reducing the brightness difference between the first display region and the second display region. Furthermore, by reducing the length of the active layer of the drive transistor of the second pixel circuit, free space can be obtained, thereby providing space for arranging data compensation units.

In some exemplary embodiments, the data compensation unit may include a first compensation electrode plate and a second compensation electrode plate. An orthographic projection of the first compensation electrode plate on the base substrate and an orthographic projection of the second compensation electrode plate on the base substrate may at least partially overlap. The first compensation electrode plate may be electrically connected to the data line and the second compensation electrode plate may be electrically connected to the first signal line. For example, the first signal line may include a first power supply line. The first power supply line may be configured to transmit a first voltage signal of a high potential. However, the embodiment is not limited thereto. For example, the first signal line may be other lines for transmitting DC signals.

In some exemplary embodiments, in a direction perpendicular to the display substrate, the display region may include a base substrate, and a semiconductor layer, a first conductive layer, a second conductive layer, a third conductive layer, and a fourth conductive layer disposed on the base substrate. For example, the semiconductor layer, the first conductive layer, the second conductive layer, the third conductive layer, and the fourth conductive layer may be sequentially disposed on the base substrate. The semiconductor layer may include active layers of transistors of the plurality of pixel circuits. The first conductive layer may at least include gates of transistors of the plurality of pixel circuits and first capacitor electrode plates of storage capacitors of the plurality of pixel circuits. The second conductive layer may at least include second capacitor electrode plates of the storage capacitors of the plurality of pixel circuits. The third conductive layer may at least include a plurality of connection electrodes. The fourth conductive layer may include a plurality of data lines. The first compensation electrode plate and the second compensation electrode plate of the data compensation unit may be located in different conductive layers among the first conductive layer, the second conductive layer, the third conductive layer and the fourth conductive layer. For example, the first compensation electrode plate of the data compensation unit may be located in the first conductive layer, and the second compensation electrode plate may be located in the second conductive layer; alternatively, the first compensation electrode plate may be located in the second conductive layer, and the second compensation electrode plate may be located in the first conductive layer. However, the embodiment is not limited thereto.

Solutions of the embodiments will be described below through some examples.

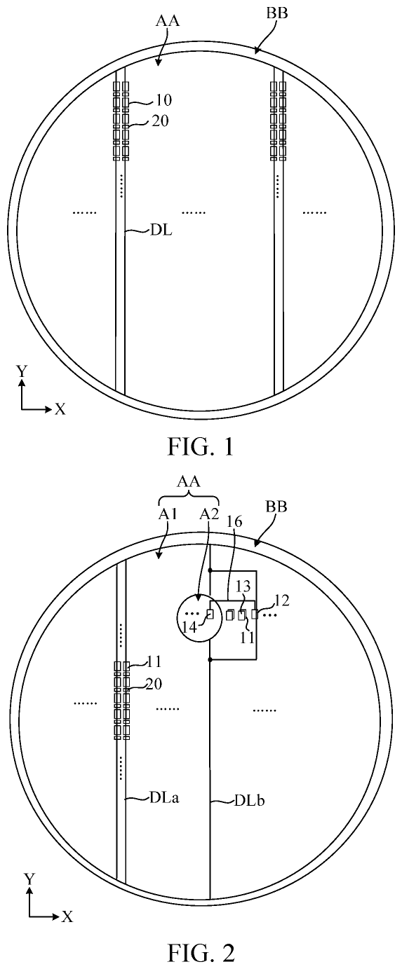

FIG. 1 is a schematic diagram of a display substrate according to at least one embodiment of the present disclosure. In some examples, as shown in FIG. 1, the display substrate may include a display region AA and a peripheral area BB surrounding the display region AA. For example, the display region AA may be circular. However, the embodiment is not limited thereto. For example, the display region AA may have other shapes such as an ellipse, a semicircle, a pentagon, a hexagon.

In some examples, the display region AA may be provided with a plurality of sub-pixels. At least one sub-pixel may include a pixel circuit and a light emitting element. The pixel circuit may be configured to drive a light emitting element connected thereto. For example, the pixel circuit may be configured to provide a drive current for driving the light emitting element to emit light. The pixel circuit may include multiple transistors and at least one capacitor, for example, the pixel circuit may be of a 3T1C (i.e., three transistors and one capacitor) structure, a 7T1C (i.e., seven transistors and one capacitor) structure, a 5T1C (i.e., five transistors and one capacitor) structure, an 8T1C (eight transistors and one capacitor) structure, or a 8T2C (eight transistors and two capacitors) structure, or the like.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted from the light emitting element may be determined as required. In some examples, the light emitting element may include an anode, a cathode, and an organic emitting layer located between the anode and the cathode. The anode of the light emitting element may be electrically connected to a corresponding pixel circuit. However, the embodiment is not limited thereto.

In some examples, one pixel unit of the display region AA may include three sub-pixels, and the three sub-pixels may be a red sub-pixel, a green sub-pixel, and a blue sub-pixel, respectively. However, the embodiment is not limited thereto. In some examples, one pixel unit may include four sub-pixels, wherein the four sub-pixels may be a red sub-pixel, a green sub-pixel, a blue sub-pixel, and a white sub-pixel respectively.

In some examples, a shape of the light emitting element may be a rectangle, a rhombus, a pentagon, or a hexagon. When one pixel unit includes three sub-pixels, light emitting elements of the three sub-pixels may be arranged side by side horizontally, side by side vertically, or in a delta-shaped arrangement. When one pixel unit includes four sub-pixels, light emitting elements of the four sub-pixels may be arranged side by side horizontally, side by side vertically, or in a square arrangement. However, the embodiment is not limited thereto.

In some examples, as shown in FIG. 1, the display region AA may include a plurality of pixel circuits 10, a plurality of data lines DL and a plurality of data compensation units 20. The plurality of data lines DL may extend in a first direction Y and are arranged sequentially in a second direction X. The plurality of pixel circuits 10 may be arranged regularly in the display region AA, for example, may be arranged in a plurality of rows and a plurality of columns. A plurality of pixel circuits arranged in the first direction Y may be referred to as a column of pixel circuits, and a plurality of pixel circuits arranged in the second direction X may be referred to as a row of pixel circuits. The first direction Y and the second direction X intersects, for example, the first direction Y may be perpendicular to the second direction X.

In some examples, as shown in FIG. 1, the plurality of data compensation units 20 may be arranged regularly in the display region AA, for example, may be arranged in a plurality of rows and a plurality of columns. A plurality of data compensation units 20 arranged in the first direction Y may be referred to as a column of data compensation units and a plurality of data compensation units 20 arranged in the second direction X may be referred to as a row of data compensation units.

In some examples, as shown in FIG. 1, in the first direction Y, data compensation units 20 and pixel circuits 10 may be arranged at intervals. A column of data compensation units 20 and a column of pixel circuits 10 may be aligned, and a row of data compensation units 20 and a row of pixel circuits 10 may be arranged at intervals in the first direction Y. For example, one row of data compensation units 20 may be arranged between two adjacent rows of pixel circuits 10. However, the embodiment is not limited thereto. For example, at least two rows of pixel circuits 10 may be arranged between adjacent at least two rows of data compensation units 20. For another example, a quantity of rows of pixel circuits arranged between at least two adjacent rows of data compensation units 20 may be the same. For another example, K1 rows of pixel circuits may be arranged between an m-th row of data compensation units and an (m+1)-th row of data compensation units, and K2 rows of pixel circuits may be arranged between the m-th row of data compensation units and an (m−1)-th row of data compensation units, wherein K1 may not be equal to K2, both K1 and K2 are integers, and m is an integer.

In other examples, data compensation units and the pixel circuits may be arranged at intervals in the second direction X. For example, in the second direction X, a column of pixel circuits and a column of data compensation units may be arranged at intervals. In other examples, data compensation units and pixel circuits may be arranged at intervals in both the first direction Y and the second direction X. For example, in the first direction Y, a row of pixel circuits and a row of data compensation units may be arranged at intervals, and in the second direction X, a column of pixel circuits and a column of data compensation units may be arranged at intervals. However, the embodiment is not limited thereto.

In some examples, as shown in FIG. 1, a data line DL of the display region AA may be electrically connected to a plurality of pixel circuits 10 arranged along the first direction Y, and the data line DL may be configured to supply data signals to the plurality of pixel circuits 10. At least one data line DL may be electrically connected to at least one data compensation unit 20. Because there is a difference in a quantity of pixel circuits to which each of the plurality of data lines DL is electrically connected, the loads of the plurality of data lines DL are different, and the loads of the plurality of data lines DL can be made substantially the same by connecting a data compensation unit 20 to at least one data line DL for load compensation. For example, the display region AA may be circular or oval. The display region AA may be divided into a middle region, a left side region and a right side region along the second direction X, data lines DL in the middle region may not need to be connected to data compensation units 20, and data lines DL in the left side region and right side region may each be electrically connected to a certain number of data compensation units 20. In this example, because a quantity of pixel circuits 10 in the middle region of the display region AA in the second direction X is more than a quantity of pixel circuits 10 in the left side region and right side region, the load of the data lines DL in the middle region is different from the load of the data lines DL in the left side region and right side region. By setting the data lines DL in the left side region and right side region to be electrically connected with at least one data compensation unit 20, the loads of the data lines DL in the left side region and right side region can be compensated so that the loads of a plurality of data lines DL in the display region AA are substantially the same to ensure the display effect of the display region AA.

In some examples, at least one data line DL may be electrically connected to a plurality of data compensation units 20 arranged along the second direction X. A plurality of data compensation units 20 arranged in the second direction X may be electrically connected through compensation connection electrodes. In other examples, at least one data line DL may be electrically connected to a plurality of data compensation units 20 arranged along the first direction Y. For example, at least one data line DL may be directly electrically connected to a plurality of data compensation units 20 arranged in the first direction Y. In other examples, at least one data line DL may be electrically connected to both a plurality of data compensation units 20 arranged in the first direction Y and a plurality of data compensation units 20 arranged in the second direction X. The quantity and manner of the data compensation units 20 electrically connected to the data line DL is not limited in the present embodiment, as long as the need for compensation of the data line DL is satisfied.

FIG. 2 is a schematic diagram of another display substrate according to at least one embodiment of the present disclosure. In some examples, as shown in FIG. 2, the display region AA of the display substrate of the present example may include a first display region Al and a second display region A2. The first display region A1 may at least partially surround the second display region A2. For example, the first display region A1 may surround the second display region A2. In some examples, the display region AA may be circular or oval and the second display region A2 may be circular or oval. However, the embodiment is not limited thereto. For example, the second display region A2 may be rectangular, semi-circular, pentagonal, or have another shape.

In some examples, as shown in FIG. 2, the second display region A2 may be a light-transmitting display region and may also be referred to as a Full Display with Camera (FDC) region; the first display region A1 may be a normal display region. For example, an orthographic projection of a photosensitive sensor (such as a camera and other hardware) on the display substrate may be located in the second display region A2 of the display substrate. In some examples, as shown in FIG. 2, the second display region A2 may be circular and a size of the orthographic projection of the photosensitive sensor on the display substrate may be less than or equal to a size of the second display region A2. However, the embodiment is not limited thereto. In other examples, the second display region A2 may be rectangular, and a size of the orthographic projection of the photosensitive sensor on the display substrate may be less than or equal to a size of an inscribed circle of the second display region A2.

In some examples, as shown in FIG. 2, the second display region A2 may be located in a middle position of a top of the display region AA. The first display region A1 may surround the second display region A2. However, the embodiment is not limited thereto. For example, the second display region A2 may be located in another position such as an upper left corner or an upper right corner of the display region AA. For example, the first display region A1 may surround at least one side of the second display region A2.

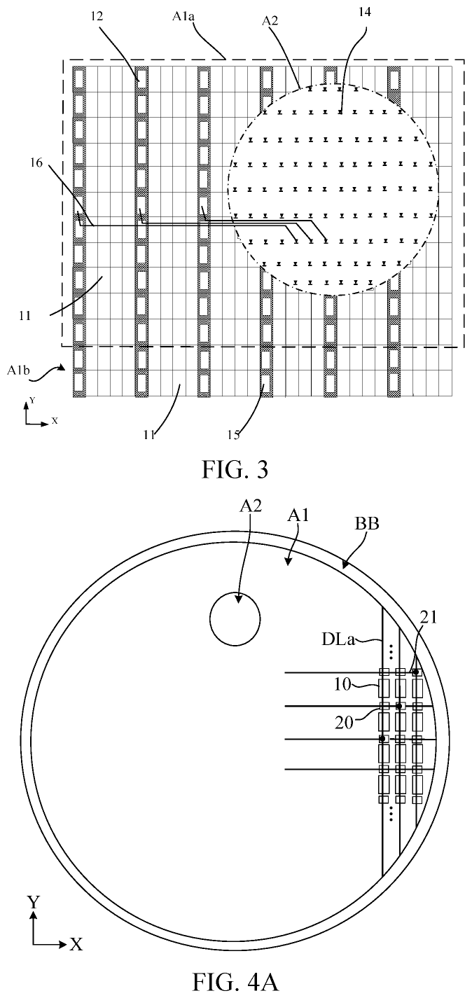

FIG. 3 is a partial schematic diagram of the display substrate shown in FIG. 2. In some examples, as shown in FIG. 3, the first display region A1 of the display substrate may include a transition region A1a and a non-transition region A1b. The transition region A1a may be located on at least one side outside the second display region A2 (for example, one side; for another example, two sides, i.e. including left and right sides; for another example, all around, i.e., including upper and lower sides and left and right sides).

In some examples, as shown in FIGS. 2 and 3, the second display region A2 may include a plurality of second light emitting elements 14 arranged in an array. The transition region Ala may include a plurality of first pixel circuits 11 and a plurality of second pixel circuits 12 arranged in an array and may include a plurality of first light emitting elements 13. At least one first pixel circuit 11 within the transition region Ala may be electrically connected with at least one first light emitting element 13, and configured to drive the first light emitting element 13 to emit light. An orthographic projection of the first light emitting element 13 on the base substrate may be at least partially overlapped with an orthographic projection of the electrically connected first pixel circuit 11 on the base substrate. At least one second pixel circuit 12 may be electrically connected to at least one second light emitting element 14 disposed within the second display region A2 through a conductive line (e.g., a transparent conductive line) 16 and configured to drive the second light emitting element 14 to emit light. For example, one end of the conductive line 16 may be electrically connected with the second pixel circuit 12 and the other end may be electrically connected with the second light emitting element 14, and the conductive line 16 may extend from the transition region A1a to the second display region A2. An orthographic projection of the second pixel circuit 12 on the base substrate may not be overlapped with an orthographic projection of the electrically connected second light emitting element 14 on the base substrate. In this example, each second light emitting element 14 in the second display region A2 may be electrically connected to the second pixel circuit 12 in the transition region A1a through at least one conductive line 16. By disposing the second pixel circuit 12 for driving the second light emitting element 14 in the transition region Ala, shielding of light by the pixel circuit may be reduced, thereby increasing a light transmittance of the second display region A2.

In some examples, the conductive line 16 may be made of a transparent conductive material, for example, it may be made of a conductive oxide material such as indium tin oxide (ITO). However, the embodiment is not limited thereto.

In some examples, as shown in FIG. 2 and FIG. 3, the non-transition region A1b may include a plurality of first pixel circuits 11 and a plurality of invalid pixel circuits 15 arranged in an array, and may include a plurality of first light emitting elements 13. At least one first pixel circuit 11 within the non-transition region A1b may be electrically connected with at least one first light emitting element 13, and an orthographic projection of the first light emitting element 13 on the base substrate may be at least partially overlapped with an orthographic projection of the electrically connected first pixel circuit 11 on the base substrate.

In some examples, as shown in FIG. 3, the transition region A1a and the non-transition region A1b may include a plurality of invalid pixel circuits 15. It may be beneficial to improving uniformity of components in a plurality of films in an etching process by arranging an invalid pixel circuit 15. For example, a structure of an invalid pixel circuit 15 may be substantially the same as structures of a first pixel circuit 11 and a second pixel circuit 12 of a row or column in which the invalid pixel circuit is located, except that it is not electrically connected to any light emitting element.

In some examples, because the first display region A1 is provided with not only a first pixel circuit 11 electrically connected with a first light emitting element 13, but also a second pixel circuit 12 electrically connected with a second light emitting element 14, a quantity of pixel circuits of the first display region A1 may be greater than a quantity of first light emitting elements 13. In some examples, as shown in FIG. 3, a region where newly added pixel circuits (including a second pixel circuit and an invalid pixel circuit) are disposed may be obtained by reducing a size of a first pixel circuit 11 in a second direction X. For example, a size of a pixel circuit in the second direction X may be smaller than a size of a first light emitting element in the second direction X. In this example, as shown in FIG. 3, every “a” columns of pixel circuits provided initially may be compressed along the second direction X, so that arrangement space for one column of pixel circuits may be newly added, and space occupied by “a” columns of pixel circuits before compression and space occupied by “a+1” columns of pixel circuits after compression may be the same. Herein, “a” may be an integer greater than 1. In this example, “a” may be equal to 4. However, the embodiment is not limited thereto. For example, “a” may be equal to 2 or 3.

In some other examples, “b” rows of pixel circuits provided initially may be compressed along a first direction Y, so that arrangement space for one row of pixel circuits is newly added, and space occupied by “b” rows of pixel circuits before compression and space occupied by “b+1” rows of pixel circuits after compression are the same. Herein, “b” may be an integer greater than 1. Or, a region in which a newly added pixel circuit is disposed may be obtained by reducing dimensions of a pixel circuit in the first direction X and the second direction Y.

In an embodiment of the present disclosure, a row of light emitting elements may refer to that pixel circuits connected to the row of light emitting elements are all connected to a same gate line (for example, a scan line). A same row of pixel circuits can be connected to a same gate line. However, the embodiment is not limited thereto.

In some examples, as shown in FIG. 2, the first display region AA may include a plurality of data lines (e.g. including data lines DLa and DLb). The data line DLa may extend in the first direction Y and is electrically connected to a plurality of pixel circuits (e.g. including a plurality of first pixel circuits 11, or may include a plurality of first pixel circuits 11 and a plurality of invalid pixel circuits) arranged in the first direction Y. The data line DLa does not need a winding design. The data line DLb can bypass the second display region A2 by a winding design. For example, the data line DLb may include three sub-data lines extending in the first direction Y and two data connection lines. A first sub-data line may be electrically connected to a plurality of pixel circuits (e.g. including a plurality of first pixel circuits 11) arranged in the first direction Y within the first display region A1 on a lower side of the second display region A2; a second sub-data line may be electrically connected to a plurality of pixel circuits (e.g. including a plurality of second pixel circuits 12, or may include a plurality of second pixel circuits 12 and a plurality of invalid pixel circuits) arranged in the first direction Y within the first display region Al along a left or right side of the second display region A2; a third sub-data line may be electrically connected to a plurality of pixel circuits (e.g. including a plurality of first pixel circuits 11) arranged in the first direction Y within the first display region Al on an upper side of the second display region A2. The first sub-data line and the second sub-data line may be electrically connected through one data connection line, and the second sub-data line and the third sub-data line may be electrically connected through another data connection line. For example, the data connection line may extend in the second direction X. The first light emitting elements 13 electrically connected to the first pixel circuits 11 connected to the first sub-data line and the second light emitting elements 14 electrically connected to the second pixel circuits 12 connected to the second sub-data line may be located in a same column.

In some examples, the first display region A1 is provided with data lines bypassing the second display region A2. Due to the winding design of this type of data lines, the capacitance of the data lines will be increased, which increases the load of the data lines, so that the data loads of data lines with a winding design and data lines without a winding design are quite different. In this example, the data load can be compensated by electrically connecting a data line without a winding design with a data compensation unit, so that the loads of a plurality of data lines in the display region are approximately the same, thereby improving the consistency of data signals and improving the display effect of the display substrate.

In some examples, the data compensation units may be arranged in a plurality of rows and a plurality of columns in the first display region A1. One row of data compensation units may be disposed between adjacent rows of pixel circuits. For example, the pixel circuits of the first display region A1 may be compressed in the first direction Y to obtain space for arranging data compensation units.

Assuming that the resolution of the display region is 384×384, a data capacitance of a region where a single pixel circuit is located is about 20 fF, and a data capacitance of a column of full of pixel circuits in the first display region of the display region can be about 384×20=7680 fF. The data capacitance of the wound part of the data line with a winding design in the first display region is about 1500 fF, the maximum data capacitance of the data line with a winding design can be about 7680+1500=9180 fF. Taking a case in which an edge pixel circuit column of the display region in the second direction X includes 20 pixel circuits as an example, and the data capacitance of the data line to which the edge pixel circuit column is electrically connected is about 20×20=400 fF. It can be seen that the difference between the data capacitances of the data line electrically connected to the edge pixel circuit column and the data line with a winding design is about 9180−400=8780 fF. Taking a case in which the capacitance of a data compensation unit is about 65 fF an example, a quantity of data compensation units required to be electrically connected to the data line electrically connected to the edge pixel circuit column can be about 8780/65=135. When the display substrate is not designed in FDC, the quantity of data compensation units required to be electrically connected to the data line to which the edge pixel circuit column is electrically connected can be about (7680−400)/65=112. Because a maximum of 384 pixel circuits can be arranged in the second direction, by longitudinally compressing the pixel circuits, there can be sufficient space to arrange the quantity of data compensation units satisfying the compensation requirement in the first direction Y. Moreover, different data lines require different data capacitance to be compensated, and the quantity of data compensation units electrically connected to a data line can be determined according to the requirement of the data capacitance required to be compensated for the data line.

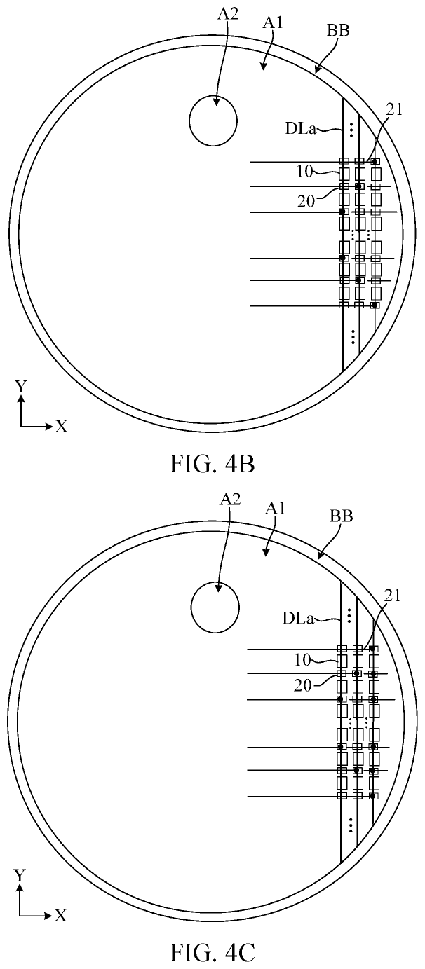

FIG. 4A is a schematic diagram of a connection between a data line and a data compensation unit according to at least one embodiment of the present disclosure. In some examples, as shown in FIG. 4A, at least one data line DLa may be electrically connected to a plurality of data compensation units 20 in a row of data compensation units. For example, in a row of data compensation units, a plurality of data compensation units 20 electrically connected to a same data line DLa may be electrically connected through compensation connection electrodes 21.

FIG. 4B is schematic diagram of another connection between a data line and a data compensation unit according to at least one embodiment of the present disclosure. In some examples, as shown in FIG. 4B, at least one data line DLa may be electrically connected to a plurality of data compensation units 20 in a plurality of rows (e.g. two rows) of data compensation units. For example, the data line DLa may be electrically connected to N data compensation units 20 in one row of data compensation units 20 and may be electrically connected to M data compensation units 20 in another row of data compensation units 20. Both N and M can be integers greater than or equal to 1. For example, N may be equal to M, or N and M may be different. Adjacent data compensation units 20 within a same row of data compensation units 20 which are electrically connected to a same data line DLa may be electrically connected through compensation connection electrodes 21.

In some examples, the first display region Al may have a first centerline in the first direction Y, an extension direction of the first centerline may be substantially parallel to the second direction X, and two rows of data compensation units 20 electrically connected to a data line DLa may be substantially symmetrical with respect to the first centerline. However, the embodiment is not limited thereto.

FIG. 4C is schematic diagram of another connection between a data line and a data compensation unit according to at least one embodiment of the present disclosure. In some examples, as shown in FIG. 4C, at least one data line DLa may be electrically connected to a plurality of data compensation units 20 in a plurality of rows of data compensation units. Adjacent data compensation units 20 within one row of data compensation units may be electrically connected to different data lines DLa. For example, at least one data line DLa may be electrically connected to a plurality of adjacent data compensation units 20 arranged along the second direction Y, and may be electrically connected to a plurality of adjacent data compensation units in a row where at least one of the data compensation units 20 is located. In a same row of data compensation units, adjacent data compensation units 20 electrically connected to a same data line DLa may be electrically connected through compensation connection electrodes 21.

In some examples, quantities of rows of data compensation units electrically connected to a plurality of data lines DLa may be the same or may be partially the same or may be different. However, the embodiment is not limited thereto.

In other examples, quantities of rows of pixel circuits spaced between at least two adjacent data compensation units within a column of data compensation units may be the same or different. For example, one row of pixel circuits or two pixel circuits may be spaced between at least two adjacent data compensation units within a column of data compensation units. The arrangement of the data compensation units in the display region is not limited in the present embodiment, so long as the uniformity of the display region is ensured.

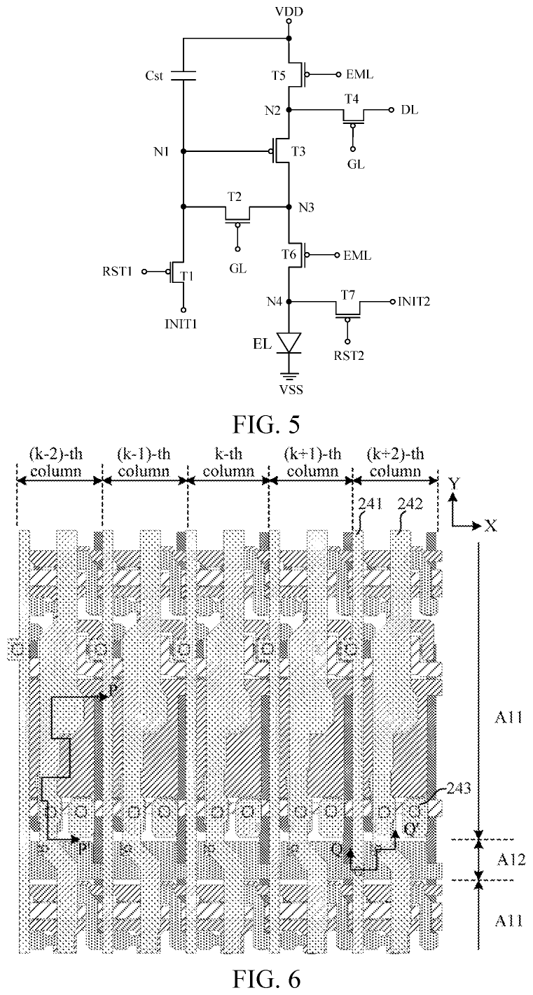

FIG. 5 is an equivalent circuit diagram of a pixel circuit according to at least one embodiment of the present disclosure. The pixel circuit of an exemplary implementation is described by taking a 7T1C structure as an example. However, the embodiment is not limited thereto.

In some exemplary embodiments, as shown in FIG. 5, the pixel circuit according to this example may include seven transistors (i.e., a first transistor T1 to a seventh transistor T7) and one storage capacitor Cst. The light emitting element EL may include an anode, a cathode and an organic emitting layer arranged between the anode and the cathode.

In some exemplary embodiments, the seven transistors of the pixel circuit may be P-type transistors, or may be N-type transistors. Use of a same type of transistors in the pixel circuit may simplify a process flow, reduce a process difficulty of the display substrate, and improve a yield of products. In some possible embodiments, the seven transistors in the pixel circuit may include a P-type transistor and an N-type transistor.

In some exemplary embodiments, the seven transistors in the pixel circuit may be low temperature poly-silicon thin film transistors, or may be oxide thin film transistors, or may use both of low temperature poly-silicon thin film transistors and oxide thin film transistors. Low Temperature Poly Silicon (LTPS) is used for an active layer of a low temperature poly silicon thin film transistor and an oxide semiconductor (Oxide) is used for an active layer of an oxide thin film transistor. A low temperature poly-crystalline silicon thin film transistor has advantages, such as a high mobility, and fast charging, etc., while an oxide thin film transistor has advantages, such as a low leakage current, etc. The low temperature poly-silicon thin film transistor and the oxide thin film transistor are integrated on one display substrate to form a low temperature poly-crystalline oxide (LTPS+Oxide) display substrate, and advantages of both the low temperature poly-crystalline silicon thin film transistor and the oxide thin film transistor can be utilized, which can achieve low frequency drive, reduce power consumption, and improve display quality.

In some exemplary embodiments, as shown in FIG. 5, the display substrate may include a first scan line GL, a data line DL, a first power supply line VDD, a second power supply line VSS, a light emitting control line EML, a first initial signal line INIT1, a second initial signal line INIT2, a second scan line RST1, and a third scan line RST2. In some examples, the first power supply line VDD may be configured to provide a constant first voltage signal Vdd to the pixel circuit, and the second power supply line VSS may be configured to provide a constant second voltage signal Vss to the pixel circuit, and the first voltage signal Vdd may be greater than the second voltage signal Vss. The first scan line GL may be configured to provide a scan signal SCAN to the pixel circuit, the data line DL may be configured to provide a data signal DATA to the pixel circuit, the light emitting control line EML may be configured to provide a light emitting control signal EM to the pixel circuit, the second scan line RST1 may be configured to provide a first reset control signal RESET1 to the pixel circuit, and the third scan line RST2 may be configured to provide a second reset control signal RESET2 to the pixel circuit.

In some examples, a second scan line RST1 connected with an n-th row of pixel circuits may be electrically connected with a first scan line GL used for an (n−1)-th row of pixel circuits, so as to be inputted with a scan signal SCAN(n−1), that is, a first reset control signal RESET1(n) is the same as the scan signal SCAN(n−1). A third scan line RST2 for the n-th row of pixel circuits may be electrically connected with a first scan line GL for the n-th row of pixel circuits, so as to be inputted with a scan signal SCAN(n), that is, a second reset control signal RESET2(n) may be the same as the scan signal SCAN(n−1). Herein, n is an integer greater than 0. Thus, signal lines of the display substrate may be reduced, and a narrow bezel design of the display substrate may be achieved. However, the embodiment is not limited thereto.

In some exemplary implementations, the first initial signal line INIT1 may be configured to provide a first initial signal to the pixel circuit, the second initial signal line INIT2 may be configured to provide a second initial signal to the pixel circuit. For example, the first initial signal may be different from the second initial signal. The first initial signal and the second initial signal may be constant voltage signals, and the magnitudes of the voltage signals may be between a first voltage signal Vdd and a second voltage signal Vss, but not limited to this. In other examples, the first initial signal and the second initial signal may be the same. And only the first initial signal line may be provided to provide the first initial signal.

In some exemplary embodiments, as shown in FIG. 5, a gate of the third transistor T3 is electrically connected with a first node N1, a first electrode of the third transistor T3 is electrically connected with a second node N2, and a second electrode of the third transistor T3 is electrically connected with a third node N3. The third transistor T3 may be referred to as a drive transistor. A gate of the fourth transistor T4 is electrically connected with the first scan line GL, a first electrode of the fourth transistor T4 is electrically connected with the data line DL, and a second electrode of the fourth transistor T4 is electrically connected with the first electrode of the third transistor T3. The fourth transistor may be also referred to as a data writing transistor. A gate of the second transistor T2 is electrically connected with the first scan line GL, a first electrode of the second transistor T2 is electrically connected with a gate of the third transistor T3, and a second electrode of the second transistor T2 is electrically connected with a second electrode of the third transistor T3. The second transistor may also be referred to as a threshold compensation transistor. A gate electrode of the fifth transistor T5 is electrically connected with the light emitting control line EML, a first electrode of the fifth transistor T5 is electrically connected with the first power supply line VDD, and a second electrode of the fifth transistor T5 is electrically connected with the first electrode of the third transistor T3. A gate of the sixth transistor T6 is electrically connected with the light emitting control line EML, a first electrode of the sixth transistor T6 is electrically connected with the second electrode of the third transistor T3, and a second electrode of the sixth transistor T6 is electrically connected with an anode of the light emitting element EL. The fifth transistor T5 and the sixth transistor T6 may be referred to as light emitting control transistors. The first transistor T1 is electrically connected with the gate of the third transistor T3 and configured to reset the gate of the third transistor T3, and the seventh transistor T7 is electrically connected with the anode of the light emitting element EL and configured to reset the anode of the light emitting element EL. A gate of the first transistor T1 is electrically connected with a second scan line RST1, a first electrode of the first transistor T1 is electrically connected with a first initial signal line INIT1, and a second electrode of the first transistor T1 is electrically connected with the gate of the third transistor T3. A gate of the seventh transistor T7 is connected with the third scan line RST2, a first electrode of the seventh transistor T7 is connected with the second initial signal line INIT2, and a second electrode of the seventh transistor T7 is connected with the anode of the light emitting element EL. The first transistor T1 and the seventh transistor T7 may also be referred to as reset control transistors. A first capacitor electrode plate of the storage capacitor Cst is electrically connected with the gate of the third transistor T3, and a second capacitor electrode plate of the storage capacitor Cst is electrically connected with the first power supply line VDD.

In this example, the first node N1 is a connection point for the storage capacitor Cst, the first transistor T1, the third transistor T3 and the second transistor T2, the second node N2 is a connection point for the fifth transistor T5, the fourth transistor T4, and the third transistor T3, the third node N3 is a connection point for the third transistor T3, the second transistor T2, and the sixth transistor T6, the fourth node N4 is a connection point for the sixth transistor T6, the seventh transistor T7, and the light emitting element EL.

A working process of the pixel circuit is explained below. The description is given by taking a case in which a plurality of transistors included in the pixel circuit shown in FIG. 5 are all P-type transistors as an example.

In some exemplary embodiments, during one-frame display time period, the working process of the pixel circuit may include a first stage, a second stage, and a third stage.

The first stage is referred to as a reset stage. A first reset control signal RESET1 provided by the second scan signal line RST1 is a low-level signal, so that the first transistor T1 is turned on, and a first initial signal provided by the first initial signal line INIT1 is provided to the first node N1 to initialize the first node N1 and clear an original data voltage in the storage capacitor Cst. The scan signal SCAN provided by the first scan line GL is a high-level signal and the light control signal EM provided by the light control line EML is a high-level signal, which disconnects the fourth transistor T4, the second transistor T2, the fifth transistor T5, the sixth transistor T6, and the seventh transistor T7. In this stage, the light emitting element EL does not emit light.

The second stage is referred to as a data writing stage or a threshold compensation stage. A scan signal SCAN provided by the first scan line GL is a low-level signal, a first reset control signal RESET1 provided by the second scan line RST1 and an emitting control signal EM provided by the emitting control line EML are both high-level signals, and the data line DL outputs a data signal DATA. In this stage, the third transistor T3 is turned on because the first capacitor electrode plate of the storage capacitor Cst is at a low-level. The scan signal line SCAN is a low-level signal, so that the second transistor T2, the fourth transistor T4, and the seventh transistor T7 are turned on. The second transistor T2 and the fourth transistor T4 are turned on, so that a data voltage Vdata output by the data line DL is provided to the first node N1 through the second node N2, the turned-on third transistor T3, the third node N3, and the turned-on second transistor T2, and the storage capacitor Cst is charged with a difference between the data voltage Vdata output by the data line DL and a threshold voltage of the third transistor T3. A voltage of the first capacitor electrode plate (i.e., the first node N1) of the storage capacitor Cst is Vdata−|Vth|, wherein Vdata is the data voltage output by the data line DL, and Vth is the threshold voltage of the third transistor T3. The seventh transistor T7 is turned on, so that a second initial signal provided by the second initial signal line INIT2 is provided to the anode of the light emitting element EL to initialize (reset) the anode of the light emitting element EL and clear a pre-stored voltage therein, so as to complete initialization, thereby ensuring that the light emitting element EL does not emit light. The first reset control signal RESET1 provided by the second scan line RST1 is a high-level signal, so that the first transistor T1 is turned off. The light emitting control signal EM provided by the light emitting control signal line EML is a high-level signal, so that the fifth transistor T5 and the sixth transistor T6 are turned off.

The third stage is referred to as a light emitting stage. The light emitting control signal EM provided by the light emitting control line EML is a low-level signal, and the scan signal SCAN provided by the first scan line GL and the first reset control signal RESET1 provided by the second scan line RST1 are high-level signals. The light emitting control signal EM provided by the light emitting control line EML is a low-level signal to turn on the fifth transistor T5 and the sixth transistor T6, and the first voltage signal Vdd output from the first power supply line VDD provides a drive voltage to an anode of the light emitting element EL through the fifth transistor T5, the third transistor T3 and the sixth transistor T6 which are turned on to drive the light emitting element EL to emit light.

In a drive process of the pixel circuit, a drive current flowing through the third transistor T3 is determined by a voltage difference between the gate and the first electrode of the third transistor T3. Because the voltage of the first node N1 is Vdata−|Vth|, the drive current of the third transistor T3 is as follows.

$$I = K \times {( Vgs - Vth )}^{2} =$$

$$K \times {[ ( V d d - V d a t a + \vert V t h \vert ) - V t h ]}^{2} = K \times {[ V d d - V d a t a ]}^{2} .$$

Herein, I is the drive current flowing through the third transistor T3, that is, a drive current for driving the light emitting element EL, K is a constant, Vgs is the voltage difference between the gate electrode and the first electrode of the third transistor T3, Vth is the threshold voltage of the third transistor T3, Vdata is the data voltage outputted by the data line DL, and Vdd is the first voltage signal outputted by the first power supply line VDD.

It may be seen from the above formula that a current flowing through the light emitting element EL is independent of the threshold voltage of the third transistor T3. Therefore, the pixel circuit according to this embodiment may better compensate the threshold voltage of the third transistor T3.

Description is given below by taking a case in which arrangement space of data compensation units is obtained by compressing pixel circuits in the first direction. In some examples, the first display region may include a first circuit region A11 and a second circuit region A12. The first circuit region A11 may include a plurality of pixel circuits and the second circuit region A12 may include a row of data compensation units. In the first direction Y, the first circuit regions A11 and the second circuit regions A12 may be arranged at intervals.

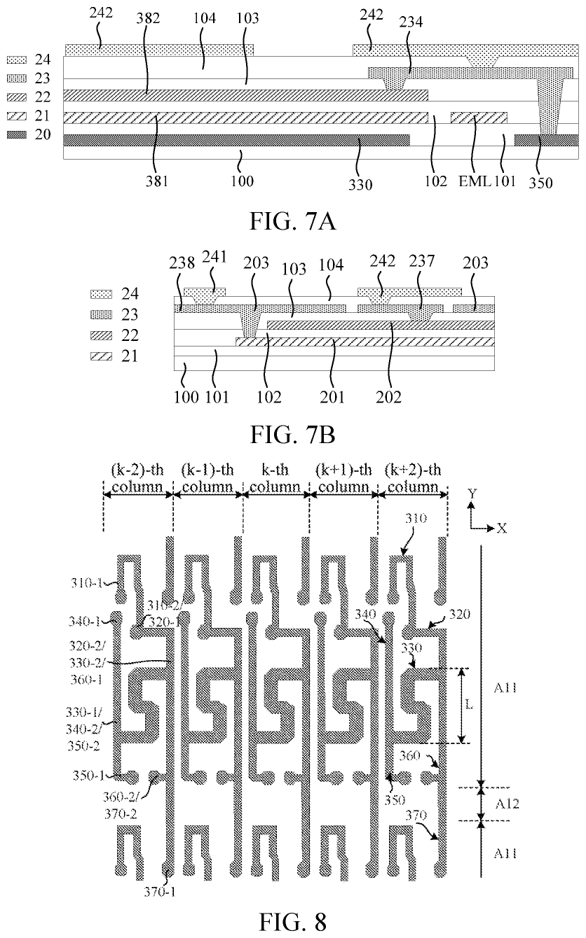

FIG. 6 is a partial top view of a first display region according to at least one embodiment of the present disclosure. FIG. 7A is a partial sectional view along a P-P′ direction in FIG. 6. FIG. 7B is a partial sectional view along a Q-Q′ direction in FIG. 6. In FIG. 6, five columns of pixel circuits (including, for example, the (k−2)-th column of pixel circuits to the (k+2)-th column of pixel circuits, k is an integer) of the first circuit region A11 and five data compensation units in a row of data compensation units are illustrated as examples.

In some examples, as shown in FIGS. 7A and 7B, in a direction perpendicular to the display substrate, the display substrate of the first display region A1 may include a base substrate 100, and a semiconductor layer 20, a first conductive layer 21, a second conductive layer 22, a third conductive layer 23, and a fourth conductive layer 24 that are sequentially disposed on the base substrate 100. In some examples, the first conductive layer 21 may also be referred to as a first gate metal layer, the second conductive layer 22 may also be referred to as a second gate metal layer, the third conductive layer 23 may also be referred to as a first source-drain metal layer, and the fourth conductive layer 24 may also be referred to as a second source-drain metal layer.

In some examples, a transparent conductive layer, a light emitting structure layer and an encapsulation structure layer may be sequentially disposed on a side of the fourth conductive layer 24 away from the base substrate 100. The transparent conductive layer may include a conductive line connecting a second pixel circuit of the first display region and a second light emitting element of the second display region. The light emitting structure layer may include at least an anode layer, a pixel definition layer, an organic light emitting layer and a cathode layer which are arranged sequentially. The anode layer may be electrically connected with a pixel circuit, the organic light emitting layer may be connected with the anode layer, the cathode layer may be connected with the organic light emitting layer, and the organic light emitting layer emits light of corresponding colors under drive of the anode layer and the cathode layer. The encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer may be arranged between the first encapsulation layer and the third encapsulation layer to form a laminated structure of inorganic material/organic material/inorganic material, which may ensure that external moisture cannot enter the light emitting structure layer. In some possible implementations, the display substrate may further include another films, such as a touch structure layer, a color filter layer, or the like, which is not limited here in the present disclosure.

In some examples, as shown in FIGS. 7A and 7B, a first insulating layer 101 may be disposed between the semiconductor layer 20 and the first conductive layer 21, a second insulating layer 102 may be disposed between the first conductive layer 21 and the second conductive layer 22, a third insulating layer 103 may be disposed between the second conductive layer 22 and the third conductive layer 23, and a fourth insulating layer 104 may be disposed between the third conductive layer 23 and the fourth conductive layer 24. In some examples, the first to fourth insulating layers 101 to 104 may all be inorganic insulating layers, or the first to third insulating layers 101 to 103 may all be inorganic insulating layers, and the fourth insulating layer 104 may be an organic insulating layer. However, the embodiment is not limited thereto.

An exemplary description will be given for a structure and a manufacturing process of the display substrate below with reference to FIGS. 6 to 15B. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made by using deposition, coating, or other processes for a material on a base substrate. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

“A and B are disposed in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In some exemplary implementations, a manufacturing process of the display substrate may include following operations.
(1) A base substrate is provided. In some examples, the base substrate 100 may be a rigid base substrate, or may be a flexible base substrate. For example, the rigid base substrate may be made of, but not limited to, one or more of glass and quartz. For example, the rigid base substrate may be made of, but not limited to, one or more of glass and quartz. The flexible base substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible base substrate may include a first flexible material layer, a first inorganic material layer, a second flexible material layer and a second inorganic material layer which are stacked. The first flexible material layer and the second flexible material layer may be made of a material such as polyimide (PI), polyethylene terephthalate (PET), or a polymer soft film on which surface treatment is performed. Materials of the first inorganic material layer and the second inorganic material layer may be silicon nitride (SiNy, y>0) or silicon oxide (SiOx, x>0), etc., which are used to improve the resistance ability against water and oxygen of the base substrate.
(2) A semiconductor layer is formed. In some examples, a semiconductor thin film is deposited on the base substrate 100 and patterned by a patterning process to form a semiconductor layer 20 disposed on the base substrate 100. In some examples, a material of the semiconductor layer 20 may be amorphous Silicon (a-Si), polycrystalline Silicon (p-Si), hexathiophene or polythiophene, and another material.

FIG. 8 is a schematic diagram of a first display region after a semiconductor layer is formed in FIG. 6. In some examples, as shown in FIG. 8, the semiconductor layer 20 of the first circuit region A11 of the first display region may at least include active layers of transistors of a plurality of pixel circuits (including, for example, a first active layer 310 of the first transistor T1, a second active layer 320 of the second transistor T2, a third active layer 330 of the third transistor T3, a fourth active layer 340 of the fourth transistor T4, a fifth active layer 350 of the fifth transistor T5, a sixth active layer 360 of the sixth transistor T6, and a seventh active layer 370 of the seventh transistor T7). The first active layer 310 of the first transistor T1 to the seventh active layer 370 of the seventh transistor T7 of a pixel circuit may be of an interconnected integral structure.

In some examples, description is given by taking a pixel circuit as an example. As shown in FIG. 8, the first active layer 310, the second active layer 320, and the fourth active layer 340 of the pixel circuit may be located on one side of the third active layer 330 of the pixel circuit in the first direction Y, and the fifth active layer 350, the sixth active layer 360, and the seventh active layer 370 may be located on the other side of the third active layer 330 of the pixel circuit in the first direction Y.

In some examples, as shown in FIG. 8, the first active layer 310 of the pixel circuit may be substantially U-shaped, the second active layer 320, the fifth active layer 350, and the sixth active layer 360 may be substantially L-shaped, the third active layer 330 may be substantially S-shaped, and the fourth active layer 340 and the seventh active layer 370 may all be substantially I-shaped. However, the embodiment is not limited thereto.

In some examples, as shown in FIG. 8, the first active layer 310 of the first transistor 31 to the seventh active layer 370 of the seventh transistor 37 of the pixel circuit may each include: a first region, a second region, and a channel region disposed between the first and second regions. The first region 310-1 of the first active layer 310, the first region 340-1 of the fourth active layer 340, the first region 350-1 of the fifth active layer 350 and the first region 370-1 of the seventh active layer 370 may be disposed separately. A second region 310-2 of the first active layer 310 may also serve as a first region 320-1 of the second active layer 320. A second region 320-2 of the second active layer 320 may also serve as the second region 330-2 of the third active layer 330 and the first region 360-1 of the sixth active layer 360. A first region 330-1 of the third active layer 330 may also serve as the second region 340-2 of the fourth active layer 340 and the second region 350-2 of the fifth active layer 350. A second region 360-2 of the sixth active layer 360 may also serve as the second region 370-2 of the seventh active layer 370.

In some examples, as shown in FIG. 8, a length L of the third active layer 330 of the third transistor (i.e., the drive transistor) T3 of the pixel circuit in the first direction Y may be about 20 microns to 35 microns, for example, may be about 25 microns. In this example, lengths of active layers of drive transistors of a plurality of pixel circuits in the first direction may be substantially the same. By reducing lengths of third active layers of drive transistors of pixel circuits, the pixel circuits may be compressed to obtain space for providing data compensation units. However, the embodiment is not limited thereto. In other examples, a length of an active layer of a drive transistor of the first pixel circuit of the first display region in the first direction may be greater than a length of an active layer of a drive transistor of the second pixel circuit in the first direction. As a length of an active layer of a drive transistor of the second pixel circuit decreases, a threshold voltage Vth of the drive transistor is positively biased, and a driving current can be increased without changing the voltage difference between a gate and a first electrode of the drive transistor. In this way, the display difference caused by excessive data load of a data line connected to the second pixel circuit can be alleviated, and the brightness difference between the second display region and the first display region can be reduced. Moreover, by reducing a length of an active layer of a drive transistor of the second pixel circuit, it is also possible to provide free space for the arrangement of the data compensation units.

In some examples, as shown in FIG. 8, a seventh active layer 370 of a seventh transistor of a pixel circuit of one first circuit region A11 may extend to another first circuit region A11 through the second circuit region A12. The seventh active layer 370 of the seventh transistor within the second circuit region A12 may divide the second circuit region A12 into a plurality of intervals in the second direction X. Data compensation units may be provided within the intervals. For example, one data compensation unit is provided for one interval.
(3) Forming a first conductive layer. In some examples, a first insulating thin film and a first conductive thin film are sequentially deposited on the base substrate 100 on which the above-mentioned patterns are formed, and the first conductive thin film is patterned by a patterning process to form a first insulating layer 101 and a first conductive layer 21 disposed on the first insulating layer 101. In some examples, the first conductive layer 21 may also be referred to as a first gate metal layer.

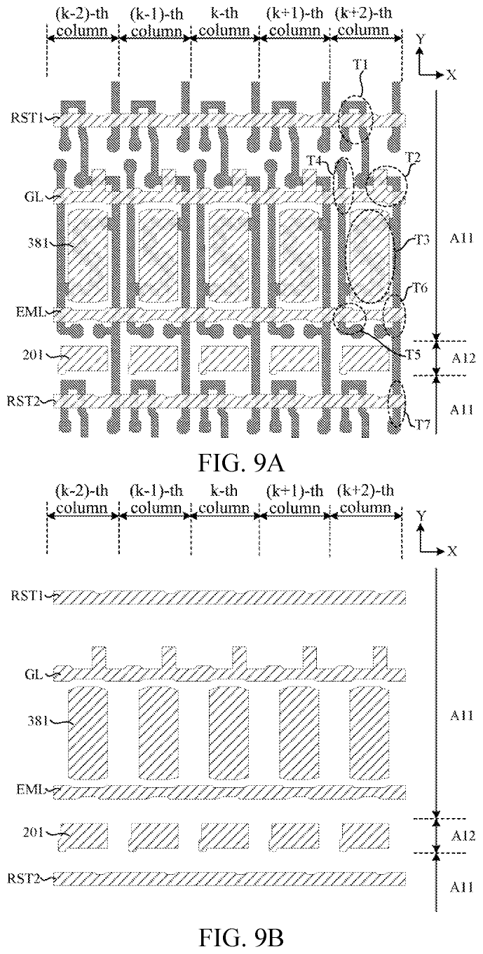

FIG. 9A is a schematic diagram of a first display region after a first conductive layer is formed in FIG. 6. FIG. 9B is a schematic diagram of a first conductive layer in FIG. 9A. In some examples, as shown in FIGS. 9A and 9B, the first conductive layer 21 of the first circuit region A12 of the first display region may include at least a first scan line GL, a second scan line RST1, a third scan line RST2, a light emitting control line EML, and a first capacitor electrode plate 381 of a storage capacitor of a pixel circuit.

In some examples, as shown in FIG. 9A, the first capacitor electrode plate 381 of the storage capacitor of the pixel circuit may simultaneously serve as a gate of the third transistor T3 of the pixel circuit. An orthographic projection of the first capacitor electrode plate 381 on the base substrate may be a rectangle, such as a rounded rectangle. In the first circuit region A11, the first scan line GL, the second scan line RST1, the third scan line RST2, and the light emitting control line EML may extend in the second direction X, and the second scan line RST1, the first scan line GL, the light emitting control line EML, and the third scan line RST2 may be arranged sequentially in the first direction Y. The third scan line RST2 electrically connected to the present row of the pixel circuits is the first scan line RST1 electrically connected to the next row of the pixel circuits.

In some examples, as shown in FIG. 9A, an overlapping region of the second scan line RST1 and the first active layer 310 may serve as a gate of the first transistor T1. An overlapping region of the first scan line GL and the second active layer 320 may serve as a gate of the second transistor T2. An overlapping region of the first scan line GL and the fourth active layer 340 may serve as a gate of the fourth transistor T4. An overlapping region of the light emitting control line EML and the fifth active layer 350 may serve as a gate of the fifth transistor T5. An overlapping region of the light emitting control line EML and the sixth active layer 360 may serve as a gate of the sixth transistor T6. An overlapping region of the third scan line RST2 and the seventh active layer 370 may serve as a gate of the seventh transistor T7. In this example, the first transistor T1 and the second transistor T2 may be double-gate transistors. However, the embodiment is not limited thereto.

In some examples, as shown in FIGS. 9A and 9B, the first conductive layer 21 of the second circuit region A12 may include at least first compensation electrode plates 201 of a plurality of data compensation units. An orthographic projection of a first compensation electrode plate 201 on the base substrate 100 may be substantially rectangular.
(4) Forming a second conductive layer. In some examples, a second insulation thin film and a second conductive thin film are sequentially deposited on the base substrate 100 where the aforementioned patterns are formed, and the second conductive thin film is patterned through a patterning process to form a second insulation layer 102 covering the first conductive layer 21 and a second conductive layer 22 disposed on the second insulation layer 102. In some examples, the second conductive layer 22 may also be referred to as a second gate metal layer.

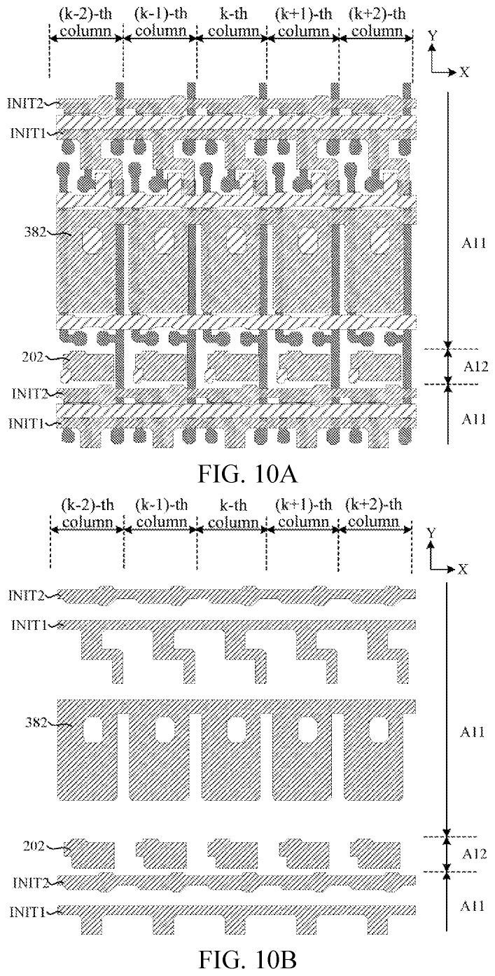

FIG. 10A is a schematic diagram of a first display region after a second conductive layer is formed in FIG. 6. FIG. 10B is a schematic diagram of a second conductive layer in FIG. 10A. In some examples, as shown in FIGS. 10A and 10B, the second conductive layer 22 of the first circuit region A11 of the first display region may include at least a first initial signal line INIT1, a second initial signal line INIT2, and a second capacitor electrode plate 382 of a storage capacitor of the pixel circuit.

In some examples, as shown in FIGS. 10A and 10B, an orthographic projection of the second capacitor electrode plate 382 of the storage capacitor of the pixel circuit on the base substrate may overlap, e.g. partially overlap, an orthographic projection of the first capacitor electrode plate 381 on the base substrate. The second capacitor electrode plate 382 may have a first opening and the orthographic projection of the first capacitor electrode plate 381 on the base substrate may cover an orthographic projection of the first opening on the base substrate. Second capacitor electrode plates 382 of storage capacitors of a plurality of pixel circuits arranged in the second direction X may be of an interconnected integral structure.

In some examples, as shown in FIGS. 10A and 10B, the first initial signal line INIT1 and the second initial signal line INIT2 of the first circuit region A11 may extend in the second direction X. The second initial signal line INIT2 may be located at a side of the first initial signal line INIT1 away from the second capacitor electrode plate 382 of the storage capacitor. The first initial signal line INIT1 may include a main body part and a protrusion part, the protrusion part may extend outwardly from the main body part in the first direction Y, and an orthographic projection of the protrusion part on the base substrate may cover a channel region of the second active layer 320 of the second transistor T2 which is not covered by a gate electrode, thereby protecting the second transistor T2 and avoiding the influence of rest of film layers on the second transistor T2.

In some examples, as shown in FIGS. 10A and 10B, the second conductive layer 22 of the second circuit region A12 may include second compensation electrode plates 202 of a plurality of data compensation units. An orthographic projection of a second compensation electrode plate 202 on the base substrate and an orthographic projection of a corresponding first compensation electrode plate 201 on the base substrate may overlap, for example, partially overlap.
(5) A third insulation layer is formed. In some examples, a third insulation thin film is deposited on the base substrate 100 where the aforementioned patterns are formed, and the third insulation thin film is patterned through a patterning process to form a third insulation layer 103.

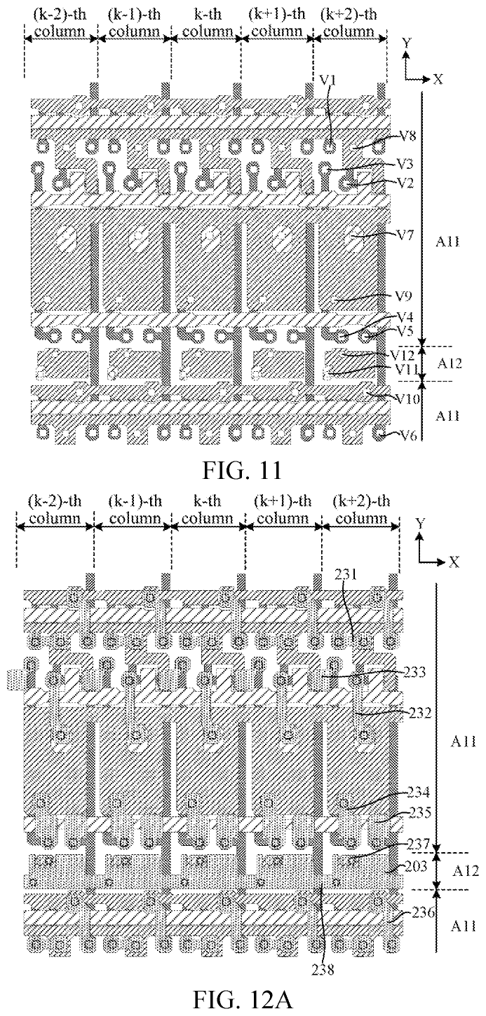

FIG. 11 is a schematic diagram of a first display region after a third insulating layer is formed in FIG. 6. In some examples, as shown in FIG. 11, the third insulating layer 103 of the first circuit region may be provided with a plurality of vias which may include, for example, a first via V1 to a tenth via V10. The third insulating layer 103, the second insulating layer 102, and the first insulating layer 101 within the first via V1 to the sixth via V6 may be removed to expose a surface of the semiconductor layer 20. The third insulating layer 103 and the second insulating layer 102 in the seventh via V7 may be removed to expose a surface of the first conductive layer 21. The third insulating layer 103 in the eighth via V8 to the tenth V10 may be removed to expose a surface of the second conductive layer 22.

In some examples, as shown in FIG. 11, the third insulating layer 103 of the second circuit region A12 may be provided with a plurality of vias which may include, for example, an eleventh via V11 and a twelfth via V12. The third insulating layer 103 and the second insulating layer 102 in the eleventh via V11 may be removed to expose part of a surface of the first compensation electrode plate 201. The third insulating layer 103 in the twelfth via V12 may be removed to expose part of a surface of the second compensation electrode plate 202.
(6) Forming a third conductive layer. In some examples, a third conductive thin film is deposited on the base substrate 100 where the aforementioned patterns are formed and the third conductive thin film is patterned by a patterning process to form a third conductive layer 23. In some examples, the third conductive layer 23 may also be referred to as a first source-drain metal layer.

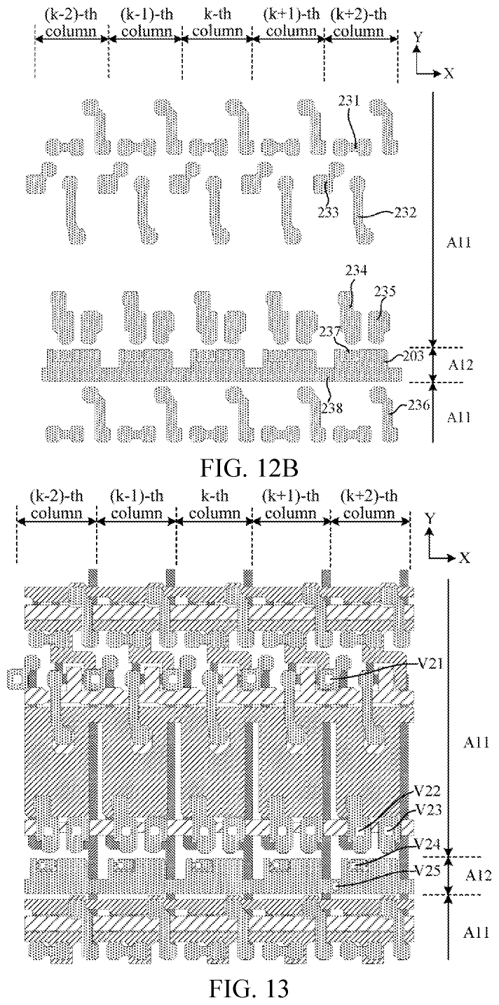

FIG. 12A is a schematic diagram of a first display region after a third conductive layer is formed in FIG. 6. FIG. 12B is a schematic diagram of a third conductive layer in FIG. 12A. In some examples, as shown in FIGS. 12A and 12B, the third conductive layer 23 of the first circuit region A11 of the first display region may include at least a plurality of connection electrodes (for example, the first connection electrode 231 to the sixth connection electrode 236).

In some examples, as shown in FIGS. 11 and 12A, the first connection electrode 231 may be electrically connected to the first region 310-1 of the first active layer 310 of the first transistor through the first via V1, and may be electrically connected to the first initial signal line INIT1 through the eighth via V8. The second connection electrode 232 may be electrically connected to the first region 320-1 of the second active layer 320 of the second transistor through the second via V2, and may be electrically connected to a gate of the third transistor through the seventh via V7. The third connection electrode 233 may be electrically connected to the first region 340-1 of the fourth active layer 340 of the fourth transistor through the third via V3. The fourth connection electrode 234 may be electrically connected to the first region 350-1 of the fifth active layer 350 of the fifth transistor through the fourth via V4, and may be electrically connected to the second capacitor electrode plate 382 of the storage capacitor through the ninth via V9. The fifth connection electrode 235 may be electrically connected to the second region 360-2 of the sixth active layer 360 of the sixth transistor through the fifth via V5. The sixth connection electrode 236 may be electrically connected to the first region 370-1 of the seventh active layer 370 of the seventh transistor through the sixth via V6, and may be electrically connected to the second initial signal line INIT2 through the tenth via V10.

In some examples, as shown in FIGS. 12A and 12B, the third conductive layer 23 of the second circuit region A12 may include a seventh connection electrode 237, a third compensation electrode plate 203, and an eighth connection electrode 238. Adjacent third compensation electrode plates 203 may be electrically connected through the eighth connection electrode 238. The third compensation electrode plates 203 and the eighth connection electrode 238 may be of an interconnected integral structure. An orthographic projection of the third compensation electrode plate 203 on the base substrate and an orthographic projection of the second compensation electrode plate 202 on the base substrate may overlap, for example, partially overlap. The third compensation electrode plate 203 may have a recess in which the seventh connection electrode 237 may be located. The seventh connection electrode 237 may be electrically connected to the second compensation electrode plate 202 through the twelfth via V12. The third compensation electrode plate 203 may be electrically connected to the first compensation electrode plate 201 through the eleventh via V11.
(7) A fourth insulation layer is formed. In some examples, a fourth insulating thin film is deposited on the base substrate 100 where the aforementioned patterns are formed and the fourth insulating thin film is patterned by a patterning process to form a fourth insulating layer 104.

FIG. 13 is a schematic diagram of a first display region after a fourth insulating layer is formed in FIG. 6. In some examples, as shown in FIG. 13, the fourth insulating layer 104 of the first circuit region A11 may be provided with a plurality of vias, which, for example, may include a twenty-first via V21 to a twenty-third via V23. The fourth insulating layer 104 in the twenty-first via V21 is removed to expose part of a surface of the third connection electrode 233. The fourth insulating layer 104 in the twenty-second via V22 is removed to expose part of a surface of the fourth connection electrode 234. The fourth insulating layer 104 in the twenty-third via V23 is removed to expose part of a surface of the fifth connection electrode 235.

In some examples, as shown in FIG. 13, the fourth insulating layer 104 of the second circuit region A12 may be provided with a plurality of vias which may include, for example, a twenty-fourth via V24 and a twenty-fifth via V25. The fourth insulating layer 104 in the twenty-fourth via V24 is removed to expose part of a surface of the seventh connection electrode 237. The fourth insulating layer 104 in the twenty-fifth via V25 is removed to expose part of a surface of the eighth connection electrode 238.
(8) Forming a fourth conductive layer. In some examples, a fourth conductive thin film is deposited on the base substrate 100 where the aforementioned patterns are formed and the fourth conductive thin film is patterned by a patterning process to form a fourth conductive layer 24. In some examples, the fourth conductive layer 24 may also be referred to as a second source-drain metal layer.

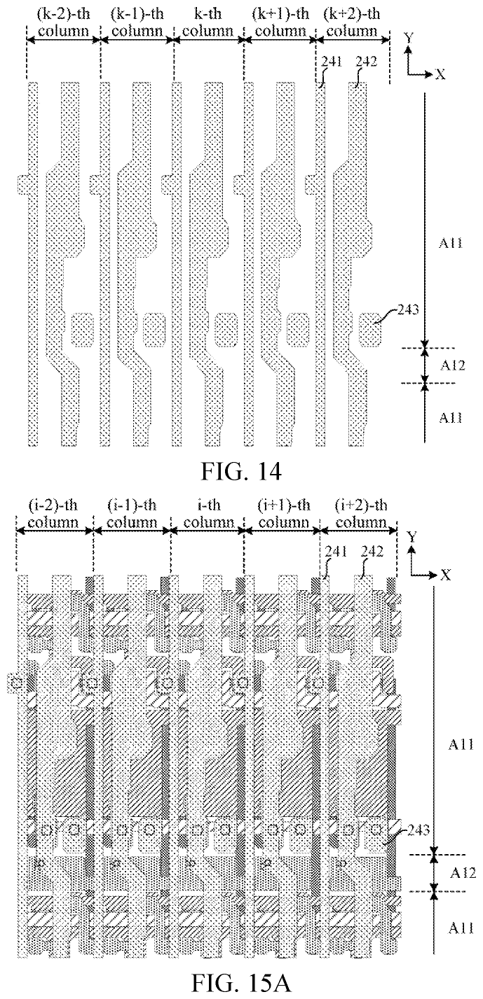

FIG. 14 is a schematic diagram of the fourth conductive layer in FIG. 6. In some examples, as shown in FIGS. 6 and 14, the fourth conductive layer 24 of the first display region may include a plurality of data lines 241, a plurality of first power supply lines 242, and a plurality of anode connection electrodes 243. The data lines 241 and the first power supply lines 242 may extend in the first direction Y and may extend from one first circuit region A11 to a second circuit region A12 and then to another first circuit region A11. In the second direction X, the data lines 241 and the first power supply lines 242 may be arranged at intervals. The anode connection electrodes 243 may be located in the first circuit region A11. The anode connection electrode 243 may be electrically connected to the fifth connection electrode 235 through the twenty-third via v23 so as to achieve an electrical connection to a second region of the sixth active layer of the sixth transistor of the pixel circuit.

In some examples, as shown in FIGS. 6 and 13, within the first circuit region A11, the data line 241 may be electrically connected with the third connection electrode 233 through the twenty-first via V21, thereby achieving an electrical connection with a first region of the fourth active layer of the fourth transistor of the pixel circuit. The first power supply line 242 may be electrically connected to the fourth connection electrode 234 through the twenty-second via V22, thereby achieving an electrical connection to a first region of the fifth active layer of the fifth transistor of the pixel circuit and the second capacitor electrode plate of the storage capacitor.

In some examples, as shown in FIGS. 6 and 13, within the second circuit region A12, the first power supply line 242 may be electrically connected to the seventh connection electrode 237 through the twenty-fourth via V24, thereby achieving an electrical connection with the second compensation electrode plate 202. The data line 241 may be electrically connected to the eighth connection electrode 238 through the twenty-fifth via V25, thereby achieving an electrical connection to the third compensation electrode plate 203 and the first compensation electrode plate 201.

In this example, the third compensation electrode plates 203 of a plurality (e.g. five) of data compensation units arranged in the second direction X may be electrically connected through the eighth connection electrodes 238 and electrically connected to a data line 241 (e.g. a data line electrically connected to the (k+2)-th column of pixel circuits) through one of the eighth connection electrodes 238. The eighth connection electrode of the present example can serve as a compensation connection electrode to realize electrical connection of a plurality of data compensation units with a same data line. The third compensation electrode plate 203 is electrically connected to the first compensation electrode plate 201 and may serve as a capacitor electrode of the data compensation unit to be electrically connected to a data line; the second compensation electrode plate 202 serves as another capacitor electrode of the data compensation unit and is electrically connected to the first power supply line. By providing data compensation units of a capacitor structure in which three layers of electrode plates are stacked, it is beneficial to arrange the data compensation units. In some examples, the capacitance value of a single data compensation unit may be about 65 fF to 100 fF. However, the embodiment is not limited thereto.

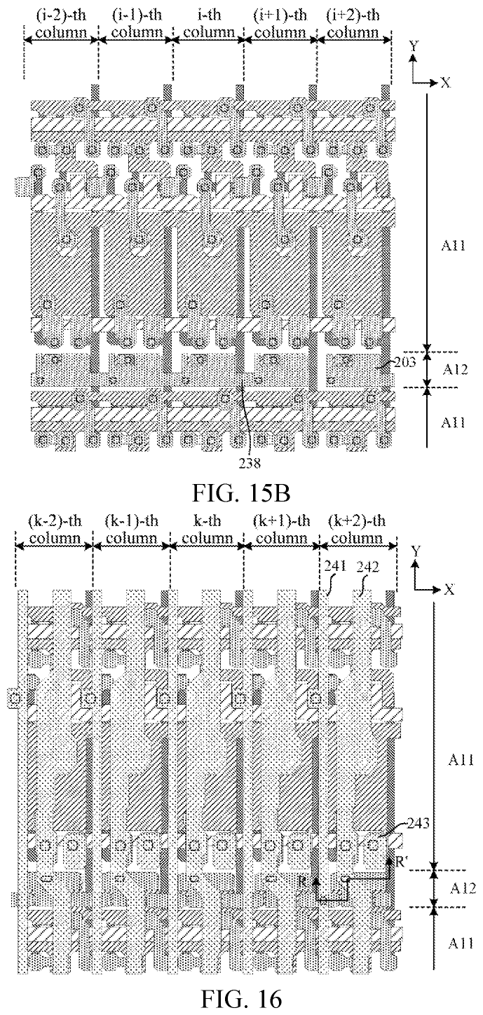

FIG. 15A is another partial top view of a first display region according to at least one embodiment of the present disclosure. FIG. 15B is a schematic diagram of a first display region after a fourth conductive layer is formed in FIG. 15A. FIGS. 15A and 15B illustrate a case in which adjacent data compensation units are disconnected. In some examples, as shown in FIGS. 15A and 15B, the third compensation electrode plates 203 of adjacent data compensation units are not electrically connected through the eighth connection electrode 238, it can be realized that the adjacent data compensation units are not electrically connected with a same data line. For example, a data compensation unit provided between adjacent pixel circuits of an (i+2)-th column of pixel circuits may be disconnected from a data compensation unit adjacent to the left side. In this example, a data compensation unit not electrically connected to a data line may be a dummy structure to ensure uniformity of the film layer structure of the display substrate.

In some examples, after a fourth conductive layer is formed, the second display region may include the base substrate and a first insulating layer 101, a second insulating layer 102, a third insulating layer 103, and a fourth insulating layer 104 arranged sequentially on the base substrate.
(9) Forming a fifth insulating layer, a transparent conductive layer, an anode layer, a pixel definition layer, an organic light emitting layer, a cathode layer, and an encapsulation structure layer sequentially.

In some examples, a fifth insulating thin film is coated on the base substrate 100 on which the above-mentioned patterns are formed and patterned by a patterning process to form a fifth insulating layer. The fifth insulating layer may be provided with a via exposing the anode connection electrode 243. Subsequently, at least one transparent conductive layer is formed, which may include a plurality of conductive lines. For example, a plurality of transparent conductive layers is formed, and an organic insulating layer may be provided between adjacent transparent conductive layers. Subsequently, a sixth insulating layer is formed. Subsequently, an anode thin film is deposited on the base substrate on which the aforementioned patterns are formed, and the anode thin film is patterned through a patterning process to form an anode layer. For example, the anode layer may include an anode of a first light emitting element located in the first display region and an anode of a second light emitting element located in the second display region. The anode of the first light emitting element may be electrically connected with an anode connection electrode of the first pixel circuit through a connection electrode of the transparent conductive layer. The anode of the second light emitting element may be electrically connected to an anode connection electrode of the second pixel circuit through a conductive line of the transparent conductive layer.

In some examples, a pixel define thin film is coated on the base on which the aforementioned patterns are formed, and a pixel define layer (PDL) is formed by masking, exposure and development processes. The pixel definition layer may be provided with a plurality of pixel openings which may expose at least part of anodes. Organic light emitting layers can be respectively formed in the plurality of pixel openings formed as previously described, and the organic light emitting layers are connected with corresponding anodes. Subsequently, a cathode thin film is deposited, and the cathode thin film is patterned through a patterning process to form a cathode layer, and the cathode layer may be electrically connected to the organic light emitting layer and the second power supply line, respectively. Then, an encapsulation layer is formed on the cathode layer. The encapsulation layer may include a stacked structure of an inorganic material/an organic material/an inorganic material.

In some exemplary embodiments, the first conductive layer to the fourth conductive layer 21 to 24 may be made of a metal material, such as any one or more of silver (Ag), copper (Cu), aluminum (Al) and molybdenum (Mo), or an alloy material of the above metals, such as AlNd alloy or MoNb alloy, which may have a single-layer structure or a multi-layer composite structure, such as Mo/Cu/Mo. The transparent conductive layer may be made of a transparent conductive material, such as Indium Tin Oxide (ITO). The first insulating layer 101 to the third insulating layer 103 may be any one or more of silicon oxide (SiOx, x>0), silicon nitride (SiNy, y>0), and silicon oxynitride (SiON), and may be in a single layer, a plurality of layers, or a composite layer. The fourth insulating layer 104, the fifth insulating layer to the sixth insulating layer may be referred to as planarization layers, and be made of an organic material, such as polyimide, acrylic, or polyethylene terephthalate. The pixel define layer may be made of an organic material, such as polyimide, acrylic, or polyethylene terephthalate. The anode layer may be made of a reflective material such as a metal and the cathode layer may be made of a transparent conductive material. However, the embodiment is not limited thereto.

A structure and a manufacturing process of the display substrate of this embodiment are merely illustrative. In some exemplary implementation, a corresponding structure may be changed and a patterning process may be added or removed according to actual needs. For example, it may be not required to provide a third compensation electrode plate, the first compensation electrode plate and the data line may be electrically connected directly through the eighth connection electrode. As another example, it may be not required to provide a third compensation electrode plate, and the first compensation electrode plate may be provided on the third conductive layer and electrically connected to the data line through the eighth connection electrode. However, the embodiment is not limited thereto.

The manufacturing process of the exemplary embodiment may be implemented using an existing mature manufacturing device, and may be compatible well with an existing manufacturing process, simple in process implementation, easy to implement, high in a production efficiency, low in a production cost, and high in yield.

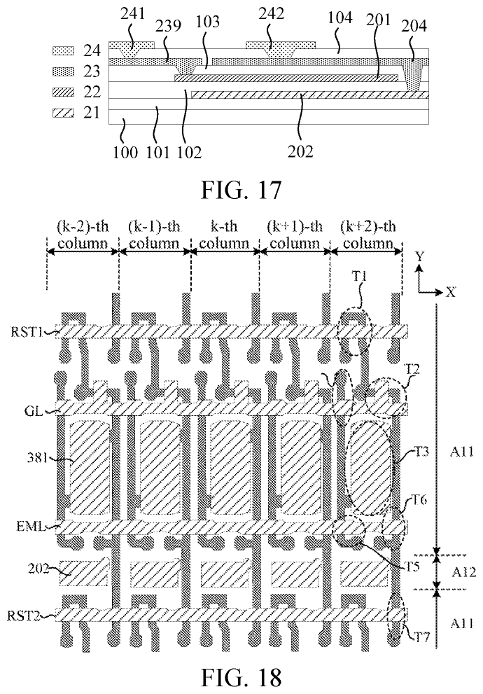

FIG. 16 is another schematic diagram of a partial structure of a first display region according to at least one embodiment of the present disclosure. FIG. 17 is a partial sectional view along an R-R′ direction in FIG. 16. In some examples, as shown in FIGS. 16 and 17, in a direction perpendicular to the display substrate, the display substrate of the first display region Al may include a base substrate 100, and a semiconductor layer 20, a first conductive layer 21, a second conductive layer 22, a third conductive layer 23, and a fourth conductive layer 24 that are sequentially disposed on the base substrate 100. A first insulation layer 101 may be arranged between the semiconductor layer 20 and the first conductive layer 21. A second insulation layer 102 may be arranged between the first conductive layer 21 and the second conductive layer 22. A third insulation layer 103 may be arranged between the second conductive layer 22 and the third conductive layer 23. A fourth insulation layer 104 may be arranged between the third conductive layer 23 and the fourth conductive layer 24.

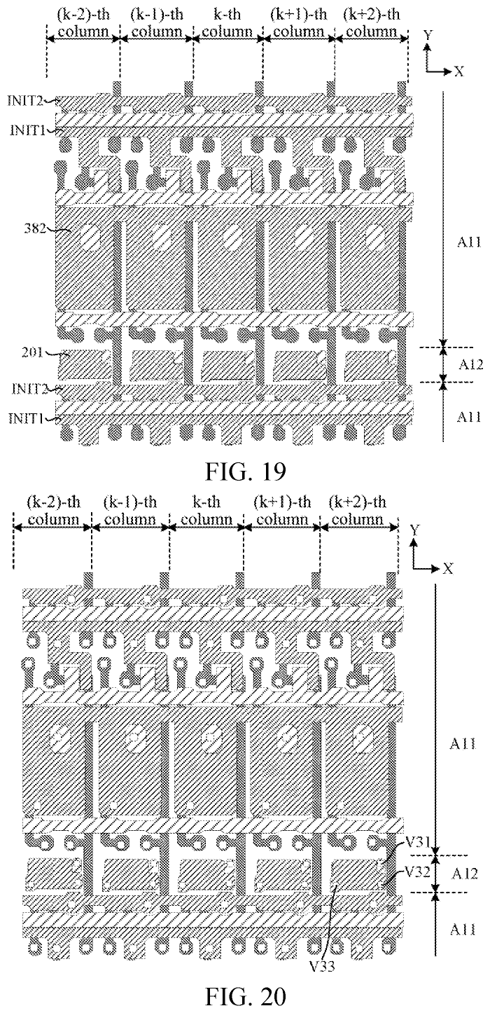

FIG. 18 is a schematic diagram of a first display region after a first conductive layer is formed in FIG. 16. FIG. 19 is a schematic diagram of a first display region after a second conductive layer is formed in FIG. 16. In some examples, as shown in FIGS. 18 and 19, the first conductive layer 21 of the second circuit region A12 may include a second compensation electrode plate 202 of the data compensation unit. The second conductive layer 22 of the second circuit region A12 may include a first compensation electrode plate 201 of the data compensation unit. An orthographic projection of the first compensation electrode plate 201 on the base substrate and an orthographic projection of the second compensation electrode plate 202 on the base substrate may overlap, for example, partially overlap.

FIG. 20 is a schematic diagram of a first display region after a third insulation layer is formed in FIG. 16. In some examples, as shown in FIG. 20, the third insulating layer 103 of the second circuit region A12 is provided with a plurality of vias, which may include, for example, a thirty-first via V31 to a thirty-third via V33. The third insulating layer 103 and the second insulating layer 102 in the thirty-first via V31 are removed to expose part of a surface of the second compensation electrode plate 202 located in the first conductive layer. The third insulating layer 103 in the thirty-third via V33 and the thirty-second via V32 are removed to expose part of a surface of the first compensation electrode plate 201 located in the second conductive layer. The thirty-third via V33 and the thirty-second via V32 may be arranged in the second direction X. An orthographic projection of the thirty-third via V33 on the base substrate may be located at one end of the first compensation electrode plate 201 in the second direction X, and an orthographic projection of the thirty-second via V32 on the base substrate may be located at the other end of the first compensation electrode plate 201 in the second direction X.

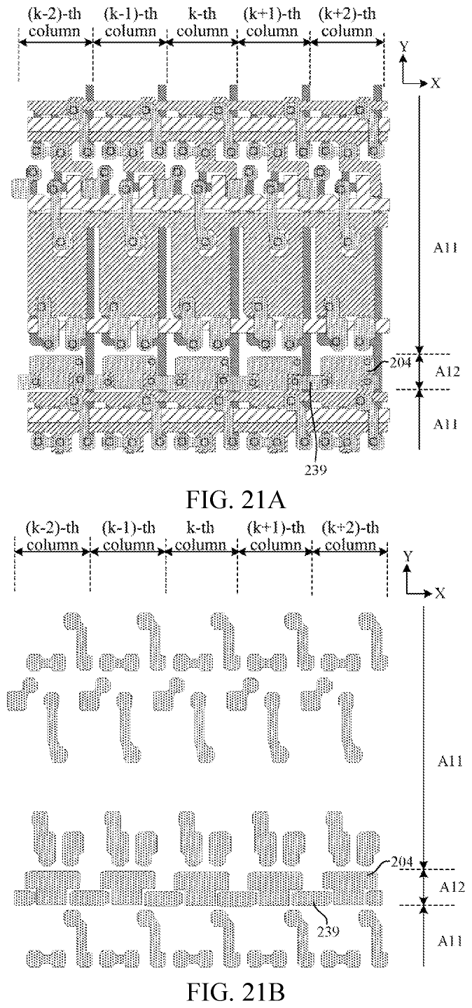

FIG. 21A is a schematic diagram of a first display region after a third conductive layer is formed in FIG. 16. FIG. 21B is a schematic diagram of a third conductive layer in FIG. 21A. In some examples, as shown in FIGS. 21A and 21B, the third conductive layer 23 of the second circuit region A12 may include a fourth compensation electrode plate 204 and a ninth connection electrode 239. An orthographic projection of the fourth compensation electrode plate 204 on the base substrate may be substantially T-shaped. The fourth compensation electrode plate 204 may be electrically connected to the second compensation electrode plate 202 through the thirty-first via V31. The ninth connection electrode 239 may extend in the second direction X. One end of the ninth connection electrode 239 may be electrically connected to one first compensation electrode plate 201 through the thirty-third via V33, and the other end thereof may be electrically connected to another first compensation electrode plate 201 through the thirty-second via V32.

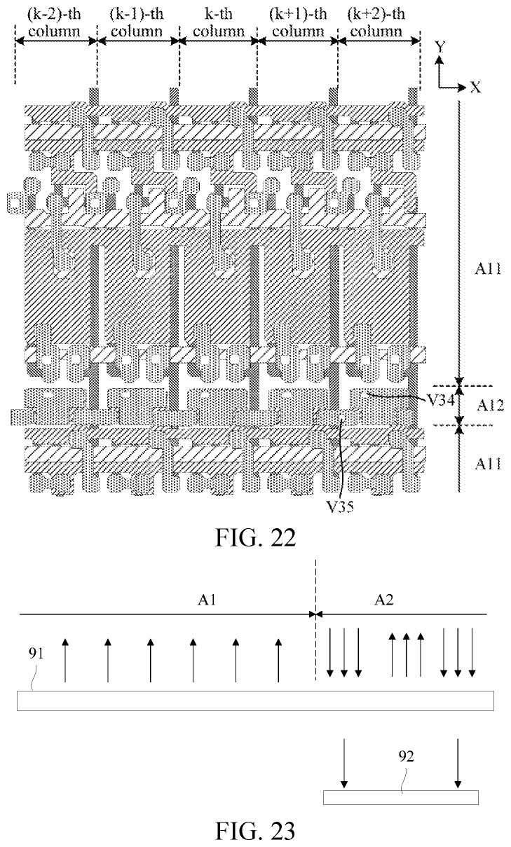

FIG. 22 is a schematic diagram of a first display region after a fourth insulation layer is formed in FIG. 16. In some examples, as shown in FIG. 22, the fourth insulating layer of the second circuit region A12 may be provided with a plurality of vias which may include, for example, a thirty-fourth via V34 and a thirty-fifth via V35. The fourth insulating layer in the thirty-fourth via V34 is removed to expose part of a surface of the fourth compensation electrode plate 204 located in the third conductive layer. The fourth insulating layer in the thirty-fifth via V35 is removed to expose part of a surface of the ninth connection electrode 239 located in the third conductive layer.

In some examples, as shown in FIGS. 16 and 22, within the second circuit region A12, the first power supply line 242 may be electrically connected to the fourth compensation electrode plate 204 through the thirty-fourth via V34, thereby achieving an electrical connection to the second compensation electrode plate 202. The data line 241 may be electrically connected to the ninth connection electrode 239 through the thirty-fifth via V35, thereby achieving an electrical connection to the second compensation electrode plate 202.

In this example, the data compensation unit may adopt a capacitor structure in which three layers of electrode plates are stacked. The first compensation electrode plate 201 can serve as a capacitor electrode of the data compensation unit and electrically connected with the data line; the second compensation electrode plate 202 and the fourth compensation electrode plate 204 are electrically connected and may serve as another capacitor electrode of the data compensation unit and are electrically connected to the first power supply line. In some examples, the capacitance value of a single data compensation unit may be about 50 fF to 85 fF. However, the embodiment is not limited thereto.

In this example, the first compensation electrode plates 201 of a plurality of data compensation units arranged in the second direction X may be electrically connected through the ninth connection electrodes 230 and electrically connected to one data line 241 through one of the ninth connection electrodes 239. The ninth connection electrode of this example can serve as a compensation connection electrode to realize an electrical connection of a plurality of data compensation units with a same data line. When adjacent data compensation units are not required to be electrically connected, the first compensation electrode plates 201 of the adjacent data compensation units are not required to be electrically connected through the ninth connection electrode, for example, the ninth connection electrode may not be provided, or the ninth connection electrode may be provided, but the ninth connection electrode is not electrically connected with the first compensation electrode plate through a via.

Rest of the structure and the preparation process of the display substrate according to this embodiment may be as described in the foregoing embodiments, and will not be repeated here.

In some examples, the film structures and sizes of a plurality of data compensation units in the display region of the display substrate may all be the same, so that the capacitance values of the plurality of data compensation units may be substantially the same. However, the embodiment is not limited thereto. For example, the film structures of at least part of the data compensation units of the plurality of data compensation units in the display region may be different (for example, the film structures of a part of the data compensation units may be as shown in FIG. 6, and the film structures of another part of the data compensation units may be as shown in FIG. 16), or the sizes of the electrode plates of the plurality of data compensation units may be different, thereby obtaining a plurality of data compensation units with different capacitance values.

In other examples, the first compensation electrode plate of the data compensation unit may be disposed at the third conductive layer or the fourth conductive layer; alternatively, the second compensation electrode plate may be provided in the third conductive layer or the fourth conductive layer. The first compensation electrode plate and the second compensation electrode plate may be located in different conductive layers among the first conductive layer to the fourth conductive layer. As long as it is satisfied that the first compensation electrode plate and the second compensation electrode plate are located in different conductive layers, there is no limitation as to which conductive layers the first compensation electrode plate and the second compensation electrode plate are located in.

At least one embodiment of the present disclosure further provides a display apparatus which includes the display substrate as described above.

In some exemplary embodiments, the display apparatus may further include a sensor located on a side of a non-display surface of the display substrate, an orthographic projection of the sensor on the display substrate is overlapped with, e.g. at least partially overlapped with, a second display region of the display substrate,.

FIG. 23 is a schematic diagram of a display apparatus according to at least one embodiment of the present disclosure. As shown in FIG. 23, a display apparatus is provide in this embodiment, which includes a display substrate 91 and a photosensitive sensor 92 located on a light exit side of a light emitting structure layer away from the display substrate 91. The photosensitive sensor 92 is located on a side of a non-display surface of the display substrate 91. An orthographic projection of the photosensitive sensor 92 on the display substrate 91 at least partially overlaps the second display region A2.

In some exemplary implementations, the display substrate 91 may be a flexible OLED display substrate, a QLED display substrate, a Micro-LED display substrate or a Mini-LED display substrate. The display apparatus may be a product having an image (including a still image or a dynamic image, wherein the dynamic image may be a video) display function. For example, the display apparatus may be: displays, televisions, billboards, digital photo frames, laser printers with display function, telephones, mobile phones, picture screens, personal digital assistants (PDA), digital cameras, portable camcorders, viewfinders, navigators, vehicles, large-area walls, information inquiry equipment (such as business inquiry equipment in e-government, banks, hospitals, power departments, etc.), monitors, etc. As another example, the display apparatus may be any one of a micro-display, a VR device including a micro-display, or an AR device.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising: a display region, wherein:
the display region comprises a base substrate and a plurality of pixel circuits, a plurality of data lines and a plurality of data compensation units arranged on the base substrate; and
at least one of the plurality of data lines is electrically connected to the plurality of pixel circuits arranged in a first direction, and is electrically connected to at least one data compensation unit of the plurality of data compensation units.

2. The display substrate according to claim 1, wherein: the plurality of pixel circuits of the display region are arranged in a plurality of rows and a plurality of columns, the plurality of pixel circuits arranged in the first direction are a column of pixel circuits, and the plurality of pixel circuits arranged in a second direction are a row of pixel circuits; the first direction is intersected with the second direction; and
the plurality of data compensation units are arranged between the plurality of rows of pixel circuits in the first direction.

3. The display substrate according to claim 2, wherein at least one row of pixel circuits is provided between at least two adjacent data compensation units arranged in the first direction.

4. The display substrate according to claim 1, wherein the at least one data line is electrically connected to the plurality of data compensation units arranged in the first direction.

5. The display substrate according to claim 1, wherein the plurality of data compensation units arranged in a second direction are one row of data compensation units; the at least one data line is electrically connected with the plurality of data compensation units in at least one row of data compensation units; the second direction is intersected with the first direction.

6. The display substrate according to claim 1, wherein the display region is a circular region.

7. The display substrate according to claim 1, wherein: the display region comprises: a first display region and a second display region, the first display region is located at at least one side of the second display region;
the plurality of pixel circuits of the display region comprises a plurality of first pixel circuits and a plurality of second pixel circuits located in the first display region; the first display region further comprises a plurality of first light emitting elements; the second display region further comprises a plurality of second light emitting elements; and
at least one first pixel circuit of the plurality of first pixel circuits is electrically connected to at least one first light emitting element of the plurality of first light emitting elements, and at least one second pixel circuit of the plurality of second pixel circuits is electrically connected to at least one second light emitting element of the plurality of second light emitting elements.

8. The display substrate according to claim 7, wherein a length of an active layer of a drive transistor of at least one second pixel circuit along the first direction is smaller than a length of an active layer of a drive transistor of at least one first pixel circuit along the first direction.

9. The display substrate according to claim 1, wherein the data compensation unit comprises: a first compensation electrode plate and a second compensation electrode plate, an orthographic projection of the first compensation electrode plate on the base substrate is at least partially overlapped with an orthographic projection of the second compensation electrode plate on the base substrate; the first compensation electrode plate is electrically connected with the data line, and the second compensation electrode plate is electrically connected with a first signal line.

10. The display substrate according to claim 9, wherein the first signal line comprises a first power supply line.

11. The display substrate according to claim 9, wherein: in a direction perpendicular to the display substrate, the display region comprises: a base substrate, and a semiconductor layer, a first conductive layer, a second conductive layer, a third conductive layer, and a fourth conductive layer disposed on the base substrate;
the semiconductor layer at least comprises: active layers of transistors of the plurality of pixel circuits;
the first conductive layer at least comprises: gate electrodes of transistors of the plurality of pixel circuits, first capacitor electrode plates of storage capacitors of the plurality of pixel circuits;
the second conductive layer at least comprises: second capacitor electrode plates of the storage capacitors of the plurality of pixel circuits;
the third conductive layer at least comprises a plurality of connection electrodes;
the fourth conductive layer at least comprises: the plurality of data lines; and
the first compensation electrode plate and the second compensation electrode plate of the data compensation unit are located in different conductive layers among the first conductive layer to the fourth conductive layer.

12. The display substrate according to claim 11, wherein the first compensation electrode plate is located in the first conductive layer and the second compensation electrode plate is located in the second conductive layer; or, the first compensation electrode plate is located in the second conductive layer, and the first compensation electrode plate is located in the first conductive layer.

13. The display substrate according to claim 9, wherein: the first compensation electrode plate is located at a side of the second compensation electrode plate close to the base substrate; and
the data compensation unit further comprises: a third compensation electrode plate electrically connected with the first compensation electrode plate; an orthographic projection of the third compensation electrode plate on the base substrate is at least partially overlapped with the orthographic projection of the second compensation electrode plate on the base substrate, the third compensation electrode plate is located at a side of the second compensation electrode plate away from the base substrate.

14. The display substrate according to claim 9, wherein: the first compensation electrode plate is located at a side of the second compensation electrode plate away from the base substrate; and
the data compensation unit further comprises: a fourth compensation electrode plate electrically connected with the second compensation electrode plate; an orthographic projection of the fourth compensation electrode plate on the base substrate is at least partially overlapped with the orthographic projection of the first compensation electrode plate on the base substrate, the fourth compensation electrode plate is located at a side of the first compensation electrode plate away from the base substrate.

15. A display apparatus, comprising the display substrate according to claim 1.

16. The display apparatus according to claim 15, further comprising:
a sensor located on a side of a non-display surface of the display substrate, wherein the display region comprises: a first display region and a second display region, the first display region is located at at least one side of the second display region; and wherein an orthographic projection of the sensor on the display substrate is at least partially overlapped with the second display region of the display substrate.

17. The display substrate according to claim 2, wherein the at least one data line is electrically connected to the plurality of data compensation units arranged in the first direction.

18. The display substrate according to claim 2, wherein the plurality of data compensation units arranged in a second direction are one row of data compensation units; the at least one data line is electrically connected with the plurality of data compensation units in at least one row of data compensation units; the second direction is intersected with the first direction.

19. The display substrate according to claim 2, wherein the display region is a circular region.

20. The display substrate according to claim 2, wherein: the display region comprises: a first display region and a second display region, the first display region is located at at least one side of the second display region;
the plurality of pixel circuits of the display region comprises a plurality of first pixel circuits and a plurality of second pixel circuits located in the first display region; the first display region further comprises a plurality of first light emitting elements; the second display region further comprises a plurality of second light emitting elements; and
at least one first pixel circuit of the plurality of first pixel circuits is electrically connected to at least one first light emitting element of the plurality of first light emitting elements, and at least one second pixel circuit of the plurality of second pixel circuits is electrically connected to at least one second light emitting element of the plurality of second light emitting elements.
